(19) United States
(12) Patent Application Publication
(10) Pub. No.: US 2026/0352101 A1
(43) Pub. Date: Nov. 5, 2026

(54) CAPACITOR SENSING AND CAPACITOR BALANCING SYSTEMS AND METHODS

(71) Applicant: pSemi Corporation, San Diego, CA (US)

(72) Inventors: Gregory Szczeszynski, Nashua, NH (US); Bassem Mohamad Alnahas, Manchester, NH (US)

(21) Appl. No.: 19/733,929

(22) Filed: Jul. 7, 2026

Related U.S. Application Data
(63) Continuation of application No. PCT/US2025/011265, filed on Jan. 10, 2025.
(60) Provisional application No. 63/620,450, filed on Jan. 12, 2024.
(60) Provisional application No. 63/620,469, filed on Jan. 12, 2024.

(51) Int. Cl. H02M 3/07; G01R 19/25; H02M 1/00; H02M 1/088

(52) U.S. Cl. CPC H02M 3/07; G01R 19/2506; H02M 1/0012; H02M 1/088

(57) ABSTRACT

Circuits and methods are provided that more effectively and efficiently implement multi-level converter circuits. According to some aspects, a method is disclosed herein. In an embodiment, the method includes providing a supply voltage to a power converter, wherein the power converter is selectively configurable in one of a plurality of states, and wherein the power converter comprises a fly capacitor. In an embodiment, the method further includes generating a sample of a voltage across the fly capacitor using a sensing circuit to yield a voltage sample, wherein a target voltage across the fly capacitor is a fraction of the supply voltage; computing a difference between the voltage sample and the target voltage; and sending the difference to a state selector configured to select from the plurality of states based on the difference.

### CROSS-REFERENCE TO RELATED APPLICATIONS

This patent application is a continuation of International Patent Application No. PCT/US2025/011265 filed Jan. 10, 2025 and entitled “CAPACITOR SENSING AND CAPACITOR BALANCING SYSTEMS AND METHODS,” which claims the benefit of and priority to U.S. Provisional Patent Application No. 63/620,450 filed Jan. 12, 2024 and entitled “CAPACITOR SENSING AND CAPACITOR BALANCING SYSTEMS AND METHODS,” and U.S. Provisional Patent Application No. 63/620,469 filed Jan. 12, 2024 and entitled “CAPACITOR SENSING AND CAPACITOR BALANCING SYSTEMS AND METHODS,” which are incorporated herein by reference in their entirety.

This patent application and International Patent Application No. PCT/US2025/011265 filed Jan. 10, 2025 and entitled “CAPACITOR SENSING AND CAPACITOR BALANCING SYSTEMS AND METHODS” are related to the following United States Provisional Patent Applications filed on Jan. 12, 2024, which are all incorporated herein by reference in their entirety:
Application No. 63/620,507 entitled “LEVEL SHIFTER AND BOOT CAPACITOR CIRCUITS, SYSTEMS, AND METHODS;”
Application No. 63/620,623 entitled “LEVEL SHIFTER AND BOOT CAPACITOR CIRCUITS, SYSTEMS, AND METHODS;”
Application No. 63/620,613 entitled “INTEGRATED CURRENT RESISTOR SENSING FOR MULTI-LEVEL CONVERTER;”
Application No. 63/620,465 entitled “STARTUP INTERLOCK FOR POWER CONVERTER CIRCUITS;”
Application No. 63/620,331 entitled “FULLY DIFFERENTIAL LEVEL SHIFT IN A NOISY ENVIRONMENT;”
Application No. 63/620,450 entitled “CAPACITOR SENSING AND CAPACITOR BALANCING SYSTEMS AND METHODS;”
Application No. 63/620,469 entitled “CAPACITOR SENSING AND CAPACITOR BALANCING SYSTEMS AND METHODS;”
Application No. 63/620,678 entitled “RECONFIGURABLE MULTI-LEVEL POWER CONVERTER TO CHARGE PUMP MODE AND FRACTIONAL CHARGE PUMP MODE;”
Application No. 63/620,417 entitled “INPUT CURRENT SLEW FOR A MULTI-LEVEL CONVERTER;”
Application No. 63/620,726 entitled “ADJUSTING OVERVOLTAGE PROTECTION BASED ON MODE OF OPERATION SYSTEMS AND METHODS;”
Application No. 63/620,737 entitled “HYBRID PEAK AVERAGE CURRENT MODE CONTROL;”
Application No. 63/620,741 entitled “CURRENT LIMITED VOLTAGE MODE CONTROL OF MULTIPLE INPUTS;”
Application No. 63/620,527 entitled “MULTI-FUNCTION COMP PIN SYSTEMS AND METHODS;”
Application No. 63/620,488 entitled “LEVEL SHIFTER AND BOOT CAPACITOR CIRCUITS, SYSTEMS, AND METHODS;”
Application No. 63/620,553 entitled “MULTI-LEVEL REVERSE CURRENT BLOCKING SYSTEMS AND METHODS;”
Application No. 63/620,638 entitled “GENERAL STARTUP FOR MULTI-LEVEL POWER CONVERTER CIRCUITS;”
Application No. 63/620,733 entitled “PRECISION ANALOG TO DIGITAL CIRCUIT TUNED VOLTAGE AND CURRENT MODE DC-DC CONVERTER;”
Application No. 63/620,738 entitled “PREDICTIVE CONTROL LOOP PRE-CHARGING DURING A MULTI-LEVEL ZONE CHANGE;”
Application No. 63/620,764 entitled “DETECTOR CIRCUIT FOR DETECTING ONE OF MULTI-INPUT CONTROLLING SIGNALS THAT CONTROLS A CONTROL LOOP CIRCUIT;”
Application No. 63/620,607 entitled “STARTUP VOLTAGE SELECTION FOR MULTI-LEVEL POWER CONVERTER CIRCUITS;”
Application No. 63/620,575 entitled “MULTI-LEVEL CAPACITOR FAULT DETECTION SYSTEMS AND METHODS;”
Application No. 63/620,582 entitled “PARALLEL OPERATION OF MULTI-LEVEL POWER CONVERTERS;” and
Application No. 63/620,763 entitled “AVERAGE AND PEAK CURRENT SENSE SYSTEMS AND METHODS.”

### BACKGROUND

This disclosure relates to electronic circuits, and more particularly for example to multi-level power converters.

Many electronic products, including mobile computing and/or communication products and components (e.g., notebook computers, ultra-book computers, tablet devices, LCD, LED displays, and the like) use multiple voltage levels for operation. For example, radio frequency (RF) transmitter power amplifiers may operate at relatively high voltages (e.g., 12V or more), whereas logic circuitry may operate at a relatively low voltage level (e.g., 1-3V) and other circuitry may operate at an intermediate voltage level (e.g., 5-10V).

Direct current power converters are often used to generate a lower or higher voltage from a common power source, such as a battery, solar cells, and rectified AC sources. Power converters which generate a lower output voltage level from a higher input voltage power source are commonly known as buck converters, so-called because the output voltage V_{OUT} is less than the input voltage V_{IN}, and hence the converter is “bucking” the input voltage. Power converters which generate a higher output voltage level from a lower input voltage power source are commonly known as boost converters, because V_{OUT} is greater than V_{IN}. Some power converters may be either a buck converter or a boost converter depending on which terminals are used for input and output. Some power converters may provide an inverted output.

One type of direct current power converter known as a multi-level power converter includes charge transfer capacitors as energy storage elements coupled by controlled switches to transfer charge from V_{IN} to V_{OUT}. Such charge transfer capacitors are commonly known as “fly capacitors” or “pump capacitors”. When a fly capacitor is used (i.e., not bypassed), the electrical energy flowing through that fly capacitor generally will either charge it or discharge it.

There is a continued need for improved circuits and methods for more effectively and efficiently operating and implementing various type of electrical circuits and devices, including for example multi-level converter circuits.

### SUMMARY

Embodiments of the present disclosure include systems, circuits, and methods for operating and implementing various electronics circuits, including multi-level converter circuits.

In some aspects, a method is disclosed. In some embodiments, the method includes providing a supply voltage to a power converter, wherein the power converter is selectively configurable in one of a plurality of states, and wherein the power converter comprises a fly capacitor. The method may further include generating a sample of a voltage across the fly capacitor using a sensing circuit to yield a voltage sample, wherein a target voltage across the fly capacitor is a fraction of the supply voltage. The method may further include computing a difference between the voltage sample and the target voltage; and sending the difference to a state selector configured to select from the plurality of states based on the difference.

In some aspects, a system is disclosed. In some embodiments, the system includes a switching circuit connected to a supply voltage terminal, wherein the switching circuit is selectively configurable into a plurality of states, wherein the switching circuit is further configured to connect to a first fly capacitor and a second fly capacitor. The system may further include a sensing circuit configured to: (1) generate a difference signal representing a difference between a measured voltage across the first fly capacitor and a target fraction of a voltage supplied to the supply voltage terminal; and (2) supply the difference signal to a state selection circuit configured to select from the plurality of states for based on the difference signal.

In some aspects, a sensing circuit is disclosed. In some embodiments, the sensing circuit is configured to connect to a first fly capacitor. The sensing circuit may include a sampling circuit configured to generate a sample of a measured voltage across the first fly capacitor. The sensing circuit may further include a comparator. The comparator may be configured to: (1) receive the sample and a target fraction of a voltage supplied to a power converter; and (2) compare the sample with the target fraction to generate a difference signal that is supplied to a state selection circuit.

The scope of the present disclosure is defined by the claims, which are incorporated into this section by reference. A more complete understanding of embodiments of the present disclosure will be afforded to those skilled in the art, as well as a realization of additional advantages thereof, by a consideration of the following detailed description of one or more embodiments. Reference will be made to the appended sheets of drawings that will first be described briefly.

### DESCRIPTION OF THE DRAWINGS

FIG. 1A is an example power converter circuit with internal input current sense, in accordance with one or more embodiments of the present disclosure.

FIG. 1B is an example power converter circuit with external input current sense, in accordance with one or more embodiments of the present disclosure.

FIG. 2A is an example dual integrated circuit (IC) power converter circuit with internal input current sense, in accordance with one or more embodiments of the present disclosure.

FIG. 2B is an example dual IC power converter circuit with external input current sense, in accordance with one or more embodiments of the present disclosure.

FIG. 3A is an example functional block diagram of a power converter circuit, in accordance with one or more embodiments of the present disclosure.

FIG. 3B is an example functional block diagram of a power converter circuit, in accordance with one or more embodiments of the present disclosure.

FIG. 4 is a diagram illustrating an example charging function in step down regulation mode of an example power converter circuit, in accordance with one or more embodiments of the present disclosure.

FIG. 5 is a diagram illustrating an example charging function in step down divide by 3 charge pump mode, in accordance with one or more embodiments of the present disclosure.

FIG. 6 is a functional block diagram illustrating aspects of an example power converter circuit, in accordance with one or more embodiments of the present disclosure.

FIG. 7 is a block diagram illustrating an example system implementing a power converter circuit, in accordance with one or more embodiments of the present disclosure.

FIG. 8A is a circuit diagram illustrating an example 3-level converter circuit, in accordance with one or more embodiments of the present disclosure.

FIG. 8B is a circuit diagram illustrating an example 4-level converter circuit, in accordance with one or more embodiments of the present disclosure.

FIG. 8C is a circuit diagram illustrating an example M-level converter circuit, in accordance with one or more embodiments of the present disclosure.

FIG. 9 is an example M-level converter circuit, in accordance with one or more embodiments of the present disclosure.

FIG. 10 is a block diagram of an example embodiment of control circuitry for an M-level converter cell, in accordance with one or more embodiments of the present disclosure.

FIGS. 11A-11C illustrate simplified diagrams of a multi-level converter circuit, in accordance with one or more embodiments of the present disclosure.

FIG. 12 illustrates an example multi-level power converter circuit coupled to a sensing circuit, in accordance with one or more embodiments of the present disclosure.

FIG. 13 illustrates another example of a multi-level power converter circuit within a system 1300, in accordance with one or more embodiments of the present disclosure.

FIG. 14 illustrates an example of a sensing circuit, in accordance with one or more embodiments of the present disclosure.

FIG. 15 illustrates another example of a sensing circuit, in accordance with one or more embodiments of the present disclosure.

FIG. 16 illustrates an example of a method of using a multi-state power converter, in accordance with one or more embodiments of the present disclosure.

FIG. 17 illustrates a switchable current source network connected to capacitor, in accordance with one or more embodiments of the present disclosure.

FIG. 18 illustrates an exemplary power converter system, in accordance with one or more embodiments of the present disclosure.

FIG. 19 illustrates another exemplary power converter system, in accordance with one or more embodiments of the present disclosure.

FIG. 20 is a detailed illustration of a controller, in accordance with one or more embodiments of the present disclosure.

FIG. 21 illustrates ranges of measured currents and voltages across fly capacitors and various thresholds, in accordance with one or more embodiments of the present disclosure.

FIG. 22 illustrates an example waveform representing the voltage across a fly capacitor, in accordance with one or more embodiments of the present disclosure.

FIG. 23 illustrates an example method, in accordance with one or more embodiments of the present disclosure.

Embodiments of the present disclosure and their advantages are best understood by referring to the detailed description that follows. It is noted that sizes of various components and distances between these components are not drawn to scale in the figures. It should be appreciated that like reference numerals are used to identify like elements illustrated in one or more of the figures.

### DETAILED DESCRIPTION

The present disclosure encompasses novel circuits, architectures, systems, and methods that more effectively and efficiently address the configuration and operation of multi-level converter circuits. It will be appreciated that various improvements disclosed herein encompass innovative circuits, hardware components, architectures, and related logic that are applicable to applications beyond multi-level converter circuits.

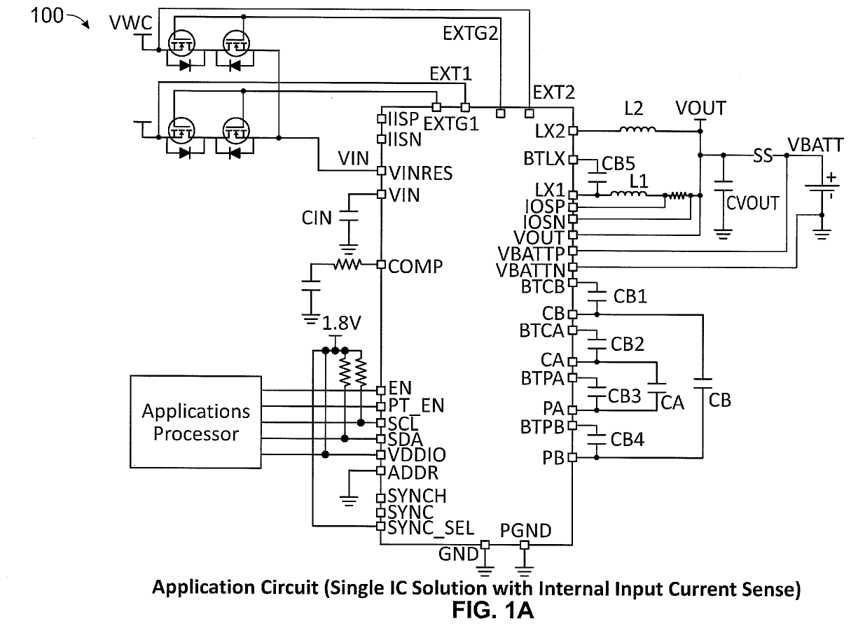

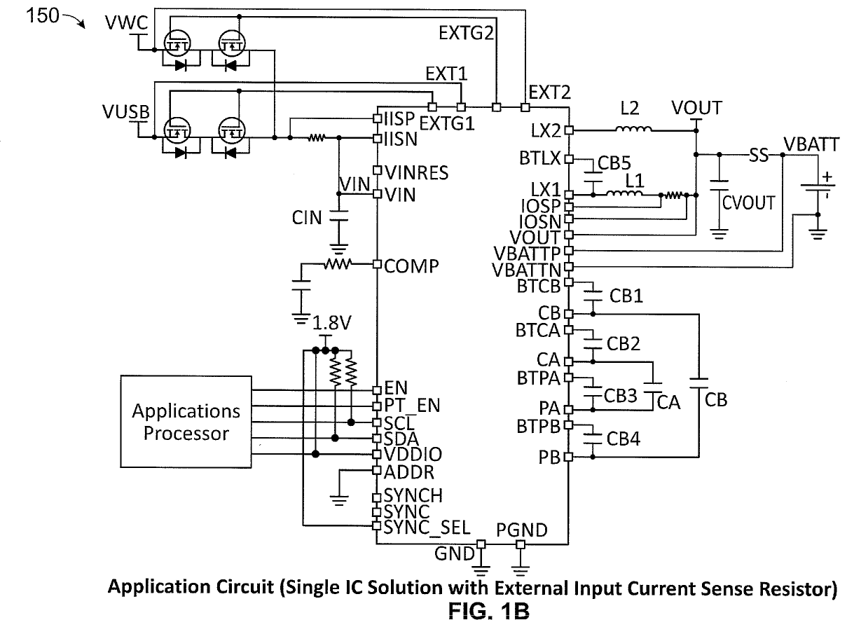

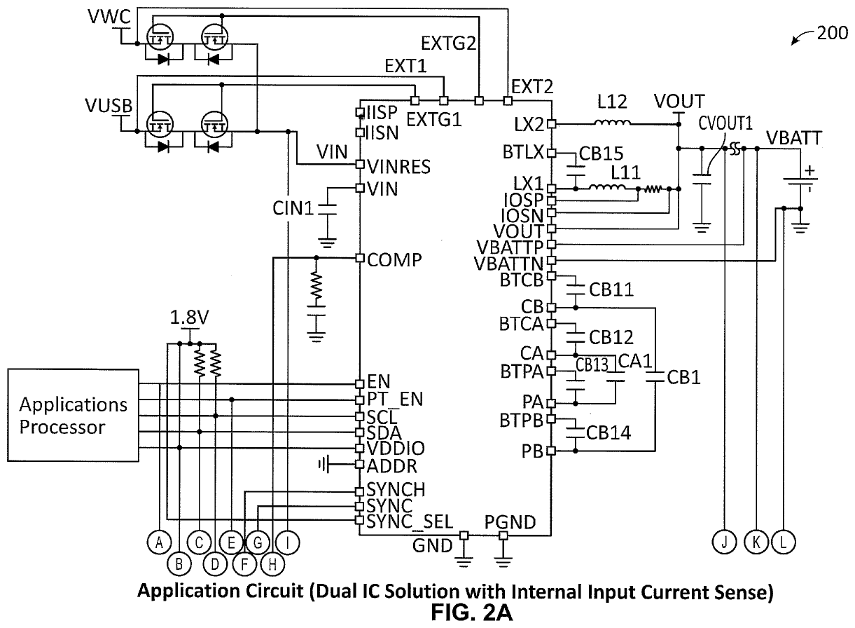

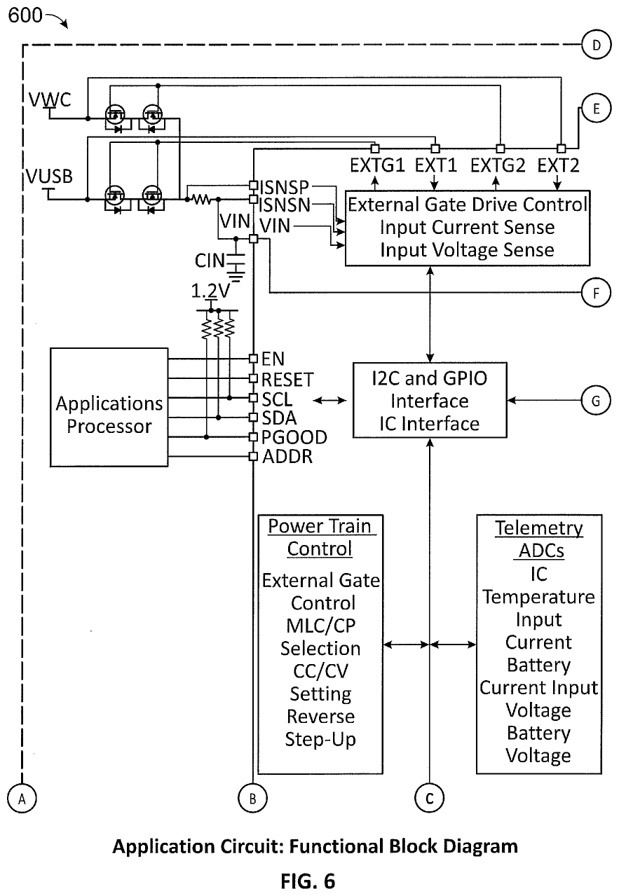

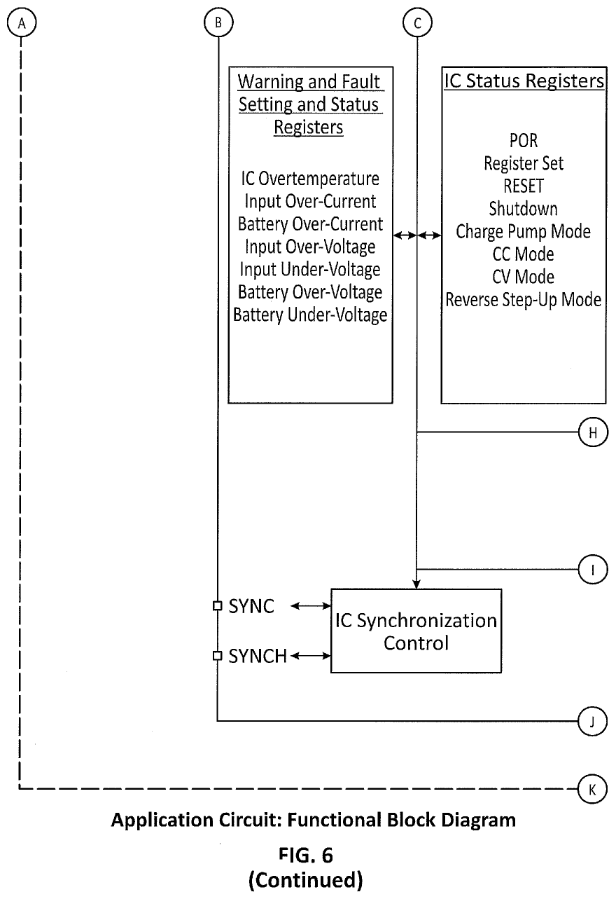

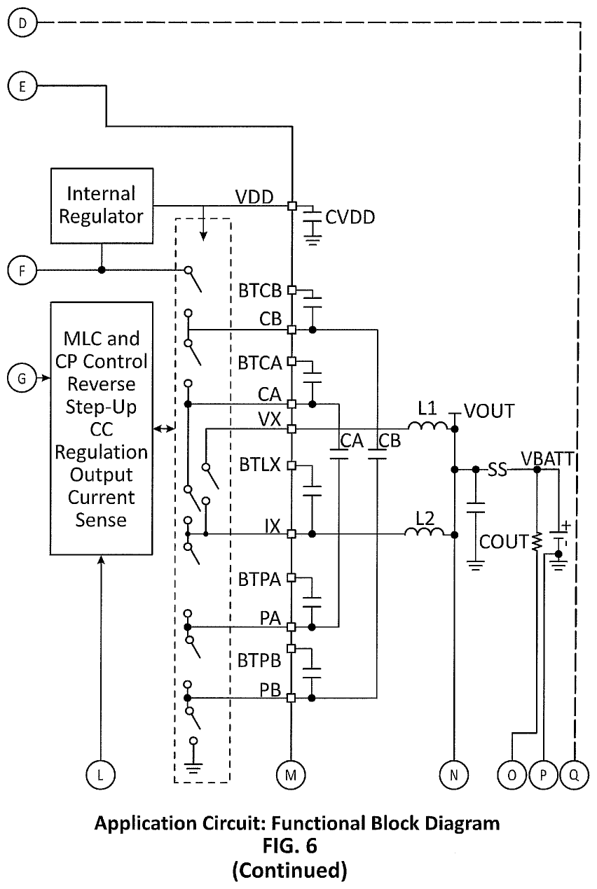

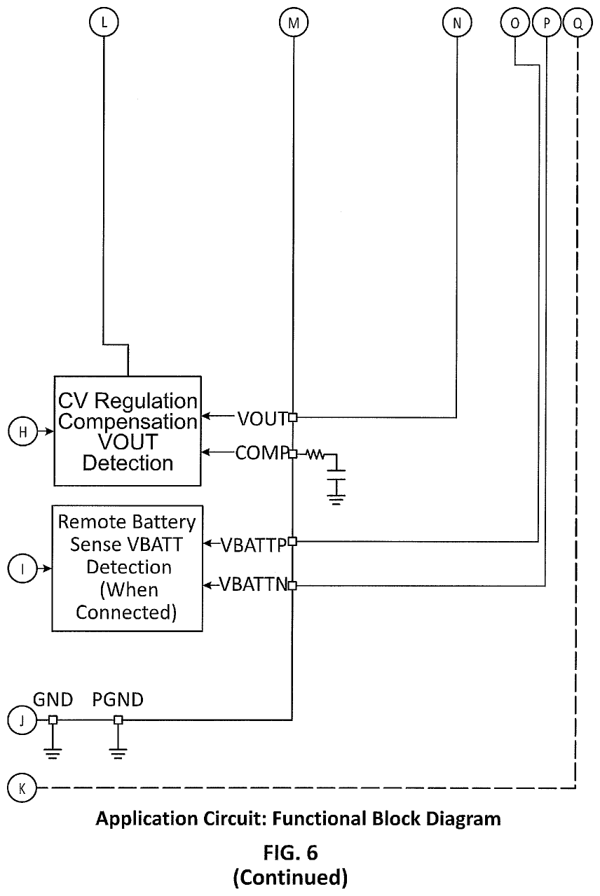

FIGS. 1-6 illustrate various embodiments of a high efficiency 4-level step-down and step-up power converter for battery charging applications, such as single cell Li-ion and Li-polymer battery applications. In the illustrated embodiments, the power converter is configured to deliver up to 5 amperes (A) of charging current in regulation mode and in a divide-by-3 charge pump mode, though other configurations are within the scope of the present disclosure. The power converter can be configured, for example, into dual ICs operation for 9 A charging current in regulation mode and in divide-by-3 charge pump mode. Although a 4-level power converter is illustrated, it will be appreciated that the embodiments described herein may be applicable to various M-level implementations, where M>=3.

In some implementations, for example, the power converter may supply an input range of approximately 4.5 V to 18 V input to support both universal serial bus (USB) and wireless inputs, and in a reverse step-up mode, the output may be programmable from 4.8 V to 16 V in 100 mV step with a programmable output current limit up to 1.7 A. This input voltage range may be used, for example, to support fast charging of single Li-Ion cells from USB and wireless input. It will be appreciated that other voltage and current ranges and limits may be implemented depending on the application. It will also be appreciated that while compatibility with USB is described herein, other wired interfaces and protocols may be implemented with the power converter of the present disclosure.

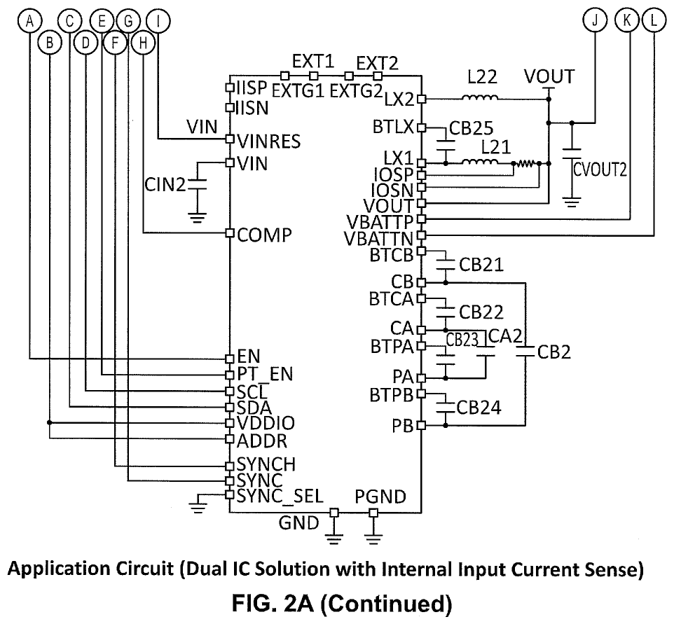

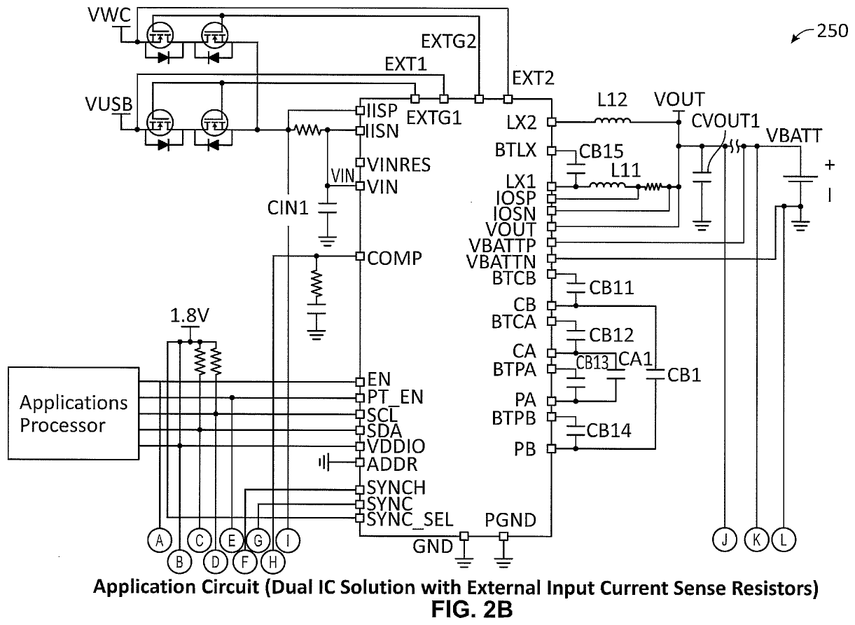

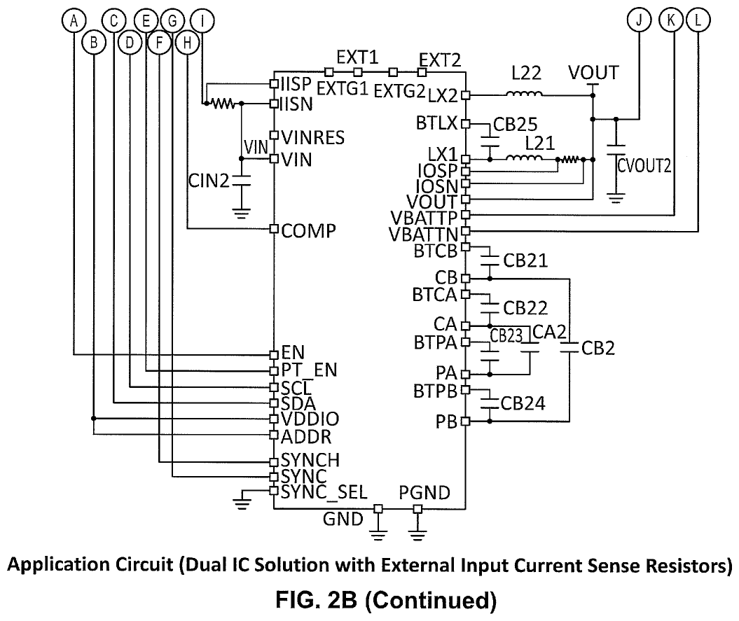

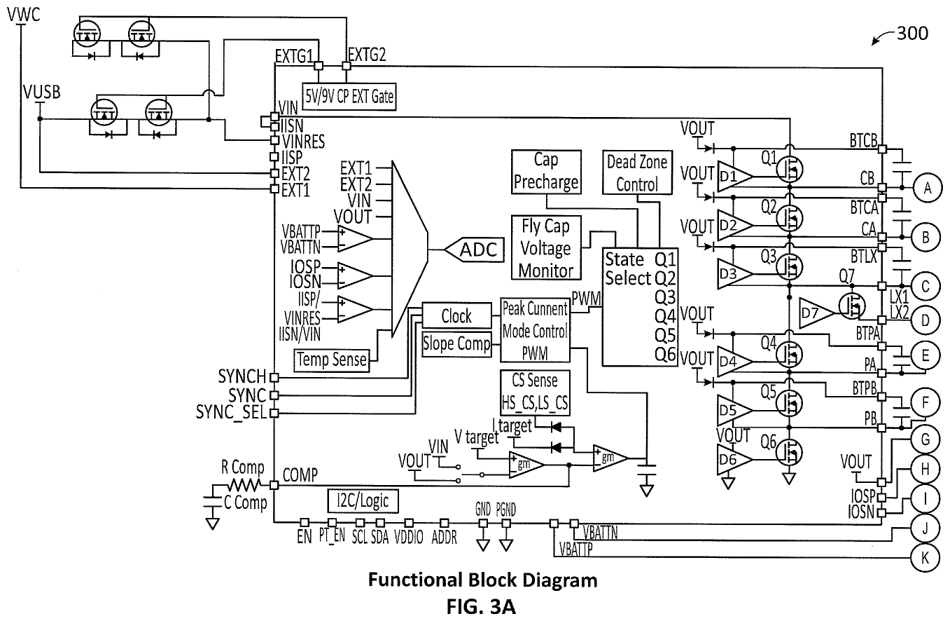

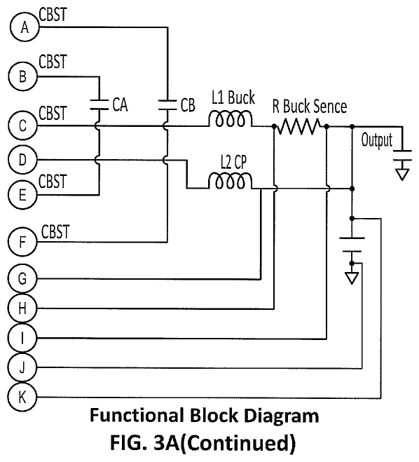

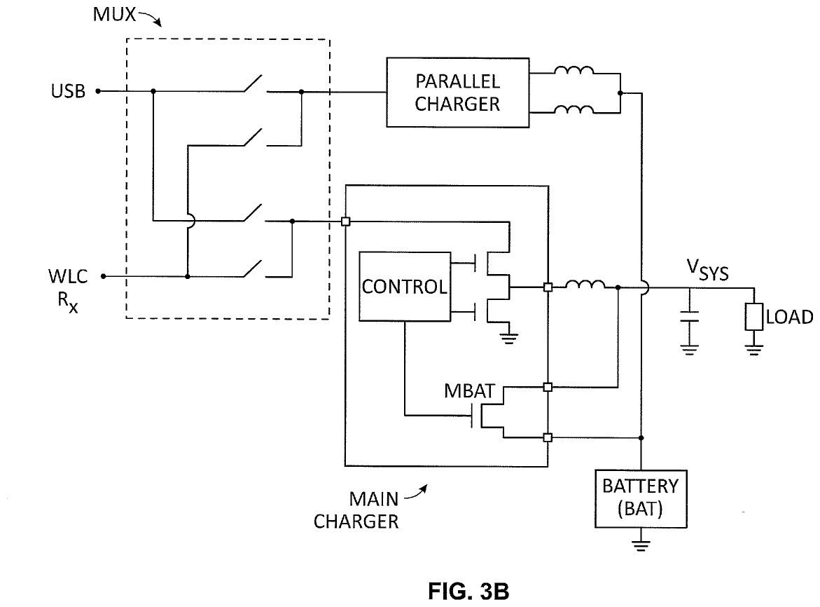

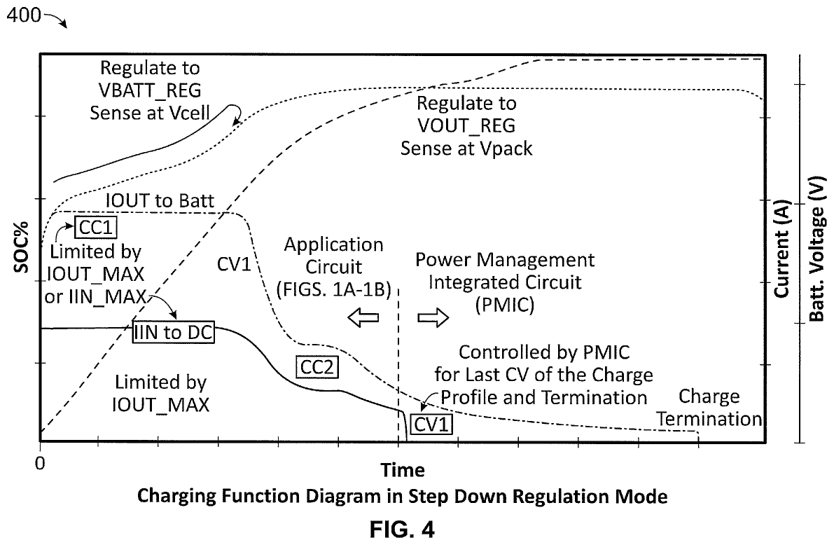

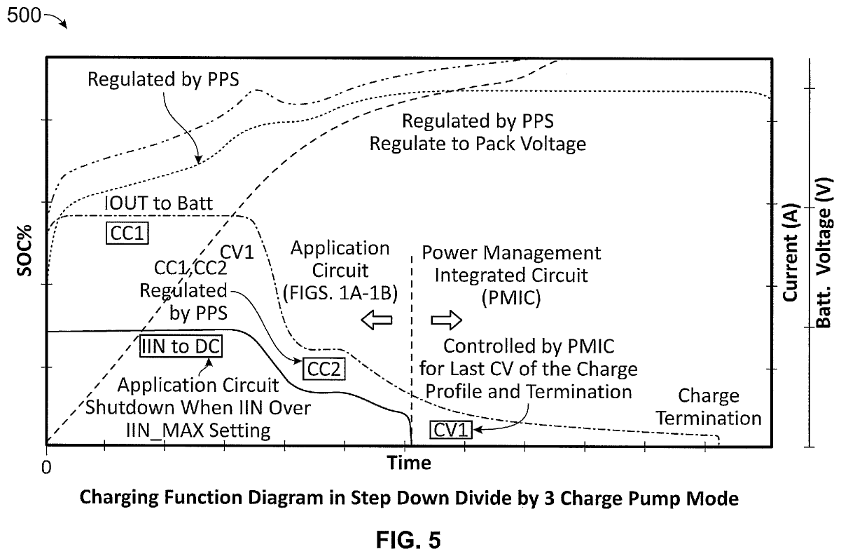

In various embodiments, the power converter may be implemented as a single integrated circuit (IC) (see, e.g., FIGS. 1A-B), dual-integrated circuits (see, e.g., FIGS. 2A-B), or in other configurations depending on the implementation. In various embodiments, the power converter may operate as a parallel charger along with a main charger, as shown in FIG. 3B, to provide the desired functionality noted herein and, for example, as illustrated in FIGS. 4 and 5 for the desired charging functionality for various applications, as would be understood by one skilled in the art. FIG. 3B may represent a system level point of view of a mobile architecture having a parallel charger and a main charger that accepts power from a wired port (e.g., a wired USB) or from a wireless interface. The parallel charger for one or more embodiments may represent an IC as illustrated in FIGS. 1-3A, for example, and may function to charge a battery for some portion of the charging profile (e.g., as shown in FIGS. 4 and 5), while the main charger charges the battery for other portions of the charging profile. In various embodiments, the parallel charger may also be configured to function as the main charger as well, depending upon the desired application. The novel architecture disclosed herein may be implemented to enable (i) improved efficiency (e.g., at 9A charging current) in a low-profile solution; (ii) low electromagnetic interference (EMI) fixed-frequency operation under heavy load conditions; (iii) input and output current and voltage, IC temperature monitoring and telemetry via inter-integrated circuit (I₂C) technology; and/or (iv) full protection including input and output under voltage lockout (UVLO), input and output over voltage protection (OVP), input and output over current protection (OCP), and IC over-temperature with fault and warning status. In some implementations, the power converter supports divide-by-3, step-down and step-up regulating modes, dual external disconnect switch control, and/or paralleled operation.

In the illustrated embodiments, the power converter is implemented as a multi-level charge pump incorporating power switches and control circuitry. The power converter's internal bias may be provided by the system battery through a VOUT connection (e.g., pin). The charging input can be USB (or other wired input) or wireless input by an external FET register control. In some implementations, the power converter may be programmed to different operating modes, which may include a step-down regulation mode, a step-down divide-by-3 charge pump mode, and a reverse step-up mode.

In a step-down regulation mode, the power converter operates as a multi-level step-down regulator to support USB power delivery (USB-PD) (or other wired protocol) or fixed input charging. During a constant-current (CC) phase, the maximum charging current may be limited for example, by configuring registers. When the input current does not reach a predetermined maximum input setting, the charge current is set to a predetermined maximum output setting. If the input current reaches the input maximum setting, then the charge current throttles and maintains input current at the input maximum setting. This allows maximum charging current while ensuring that the charge current does not go above a battery maximum current rating and the input current does not trip adapter over-current protection.

During a constant-voltage (CV) phase, the CV regulation may be limited, for example, by configuring registers. In operation, a single-wire sense pin or other sensor is configured to sense the output voltage VOUT, which is compared to a predetermined value stored in a register, VOUT_REG. The voltage differential between the battery's positive terminal and negative terminal is sensed and compared to a predetermined value stored in a register, VBATT_REG. In some implementations, a single-wire sense pin or other sensor senses VBATTP (battery voltage at positive terminal) and a single-wire sense pin or other sensor senses VBATTN (battery volage at negative terminal). The CV regulates to the lower of the two settings. If the VOUT sensed voltage reaches VOUT_REG first, then CV is regulated to VOUT_REG. If the VBATTP sensed voltage reaches VBATT_REG first, then CV is regulated to VBATT_REG. This provides a fast battery top off while preventing voltage above safety limit.

In a step-down divide-by-3 charge pump mode (which may be selected, for example, by setting a corresponding register), the power converter is configured as a divide-by-3 step-down charge divider to support USB-Programmable Power Supply (USB-PPS) or other charging protocol or programmable input charging. In some embodiments, the power converter allows the USB-PPS adapter to control voltage and current and ignores conflicting settings (e.g., settings stored in registers for IOUT_MAX, VOUT_REG and VBATT_REG). In this mode, the power converter monitors an IIN_MAX setting, shuts down the power train (which includes switches to configure, enable and disable various modes of operation) and disconnects external FET when IIN current exceeds IIN_MAX setting. In the illustrated embodiment, the output current is up to 10 A in dual IC operation and 5 A in single IC operation.

In a reverse step-up mode (which may be selected, for example, by setting a corresponding register) the power converter is configured as a multi-level step-up regulator to power peripheral device(s) connected to USB (or other wired protocol or standard) or wireless input. The power converter draws power from the system battery and regulates VIN to the VOUT_REG programmable setting of 4.8V to 16V. The VIN output current limit may be set, for example, by an IIN_MAX register.

In some embodiments, to enable the IC, both an EN pin and an IC_EN bit are set to logic high (1). When either the EN pin or IC_EN bit is set to logic low (0), the IC is disabled. After the IC is enabled, the POR status bit sets to 1 to indicate the IC has a fresh power up.

In some embodiments, the power converter provides a gate driver to control two external N-channel MOSFETs and sense inputs to monitor source input voltage at each FET. The external FETs may be controlled by registers (e.g., 1-bit registers V_EXTG, EXTG EN and EXTGX). The V_EXTG bit sets the gate drive voltage and can be set to 9V or 5V, in the illustrated embodiment. The EXTGX bits select which FET(s) to turn on. The EXTG EN bit enables the gate driver to turn on the selected FET(s). In various embodiments, the external FET can be turned on or off independently from other IC operations except when the IC is disabled. The EXT EN IND status bit set to 1 when external FET is enabled. When a fault is detected and triggers a shutdown, the external FET may be turned off automatically. If EXT1 or EXT2 detects an OVP, then the respected FET would not turn on from the off mode.

In various embodiments, the power train is enabled after all the registers have been initialized and the target input external FET is turned on. Sufficient time based on capacitance on the power path may be configured between the external FET on time and the power train on time to minimize in-rush current. Next, both PT_EN pin and PT_EN bit are set to logic high (1) to turn on the power train. When either PT_EN pin or PT_EN pin is logic low, the power train is off. In dual IC operation, the slave IC power train may be configured to turn on first before the master IC. The COMP, SYNC and SYNCH pins from two ICs gate the power train and synchronize the operation. The SYNC_SEL pin sets the IC to master mode or slave mode. IC internal fault and programmable fault detection shuts down the power train operation when fault is detected.

In a reverse step-up mode (which may be selected, for example, by setting a corresponding register), the power converter is configured as a multi-level step-up regulator to power peripheral device(s) connected to USB (or other wired port) or wireless input. The power converter draws power from the system battery and regulates VIN pin to a VOUT_REG programmable setting of 4.8V to 16V. The VIN output current limit is set by IIN_MAX register.

To enable the IC, both the EN pin and IC_EN bit are set to logic high (1). When either EN pin or IC_EN bit is set to logic low (0), the IC is disabled. After the IC enables, the POR status bit sets to 1 to indicate the IC has a fresh power up. The power converter provides a gate driver to control two external N-channel MOSFETs and sense inputs to monitor source input voltage at each FET. The external FETs are controlled by register bits, such as V_EXTG, EXTG EN and EXTGX. The V_EXTG bit sets the gate drive voltage and can be set to 9V or 5V, for example. The EXTGX bits select which FET(s) to turn on. The EXTG EN bit enables the gate driver to turn on the selected FET(s). The external FET can be turned on or off independently from other IC operation except when the IC is disabled. The EXT EN IND status bit set to 1 when external FET is enabled.

When a fault is detected and triggers a shutdown, the external FET may be turned off automatically. If EXT1 or EXT2 detects an OVP, then the respective FET would not turn on from off mode. The power train is enabled after all the registers have been initialized and the target input external FET is turned on. Sufficient time based on capacitance on the power path should be given between external FET on time to power train on time to minimize in-rush current. Next, both PT_EN pin and PT_EN bit are set to logic high (1) to turn on the power train. When either PT_EN pin or PT_EN pin is logic low, the power train is off. In dual IC operation, the slave IC power train is turned on before the master IC. The COMP, SYNC and SYNCH pins from the two ICs gate the power train and synchronize the operation. SYNC_SEL pin sets the IC to master mode or slave mode. IC internal fault and programmable fault detection shuts down power train operation when a fault is detected.

In accordance with various embodiments, an example power converter initialization, an example power up sequence, and an example fault handling will now be described for the three different operating modes. In an example step-down regulation mode, the initialization and power up sequence uses EXT1 as an example. The same sequence may apply to EXT2 with the only change in EXTGX bit and related EXT2 register settings. First, pull EN to logic high and then set IC_EN bit=1 at 100 us (TBD) after EN is logic high to enable IC. IC startup from POR stage, POR bit reports 1 indicating fresh IC startup. Next, the POR bit is read to confirm the IC is enabled. The FREQUENCY register is then set to a desired setting. In dual IC operation, both ICs are set to the same frequency setting. The VOUT_REG register is set to the target regulation voltage on the VOUT sense pin in CV operation. The VBATT_REG register is set to the target regulation voltage on the VBATTP sense pin in CV operation. The IOUT_MAX register is set to the target maximum charger current in CC operation, and the IIN_MAX register is set to a value below the adapter current limit. Next, the FAULT and WARNING registers was set to a desired setting. Each Fault and Warning enables at a different time based on IC status and operating mode. The WATCHDOG register is then set to a desired setting.

The MODE register and other related registers are set for step-down regulation mode, including power train setup and enablement of an external FET, while checking for faults. In a dual IC operation, the external FETs are controlled by the master IC. If a fault (e.g., OVP event) is detected, then a shutdown register may be set to “1” to indicate a fault shutdown event and a sequence to enable the external FET after the shutdown fault is initiated. Next, the power train is enabled. In a dual IC operation, the slave IC power train is turned on before the master IC. After the power train is enabled, a bit may be set to indicate that the power train is ready and charging the battery. In some embodiments, a watchdog timer may be set to periodically check the IC status during charging operation.

If a fault event is detected, then the IC determines which faults events were triggered, such as the power train may be set to enable but it is off due to fault(s), an external FET is set to enable but the FET is off due to fault(s). The shutdown procedure may include resetting register values and repeating setup steps of enabling the power train, external FET, or other component that is disabled due to a fault.

An example step-down divide-by-3 power converter mode initialization and power up sequence will now be described. The initialization and power up sequence uses EXT1 as an example, but it will be appreciated that the same sequence applies to EXT2 with a change in EXTGX bit and related EXT2 register settings. The EN is pulled to logic high and then IC_EN bit=1 at 100 us (TBD) after EN is logic high to enable IC. The IC starts up from POR stage, POR bit reports 1 indicating fresh IC startup. The POR bit is read to confirm the IC is enabled. The FREQUENCY register is set to a desired setting. In dual IC operation, both ICs are set to the same frequency setting. The IIN_MAX register is set to a value below the adapter current limit. VOUT_REG, VBATT_REG and IOUT_MAX registers are not used in step-down divide-by-3 charge pump mode. Voltage and current regulation in step-down divide-by-3 charge pump mode may be controlled by the PPS adapter. The FAULT, WARNING, and WATCHDOG registers are set to desired settings. Each Fault and Warning enables at different time based on IC status and operating mode.

The MODE register and other registers are set for step-down divide-by-three mode, including power train setup and external FET setup, while checking for faults. If a fault (e.g., OVP event) is detected, then a shutdown register may be set to “1” to indicate a fault shutdown event and a sequence to enable the power train or external FET, as appropriate, after the shutdown fault is initiated. Next, the power train is enabled. After the power train is enabled, a bit may be set to indicate that the power train is ready and charging the battery. In some embodiments, a watchdog timer may be set to periodically check the IC status during charging operation. Voltage and current regulation in step-down divide-by-3 charge pump mode may be controlled by the PPS adapter.

If a fault event is detected, then the IC determines which faults events were triggered, such as the power train may be set to enable but it is off due to fault(s), or an external FET is set to enable but the FET is off due to fault(s). The shutdown procedure may include resetting register values and repeating setup steps of enabling the power train, external FET, or other component that is disabled due to a fault.

An example reverse step-up mode initialization and power up sequence will now be described. This initialization and power up sequence uses EXT2 as an example, but the same sequence applies to EXT1 with the change in EXTGX bit and related EXT1 register setting. The value EN is pulled to logic high and then IC_EN bit is set to 1 at 100 us (TBD) after EN is logic high to enable IC. The IC starts up from the POR stage, and the POR bit reports 1 indicating a fresh IC startup. The POR bit is read to confirm the IC is enabled. Next, the FREQUENCY register is set to a desired setting. In dual IC operation, both ICs are set to the same frequency setting. The VOUT_REG register is set to the target regulation voltage at VIN. Next, the IIN_MAX register is set to the target current limit. VBATT_REG and IOUT_MAX registers are not used in reverse step-up mode. FAULT, WARNING, and WATCHDOG registers are set to desired settings. Each Fault and Warning enables at a different time based on IC status and operating mode.

The MODE register and other registers are set for reverse step-up mode, including power train setup and external FET setup, while checking for faults. If a fault (e.g., OVP event) is detected, then a shutdown register may be set to “1” to indicate a fault shutdown event and a sequence to enable the power train or external FET, as appropriate, after the shutdown fault is initiated. Next, the power train is enabled. After the power train is enabled, a bit may be set to indicate that the power train is ready and charging the battery. In some embodiments, a watchdog timer may be set to periodically check the IC status during charging operation. Voltage and current regulation in step-down divide-by-3 charge pump mode may be controlled by the PPS adapter. In dual IC operation, the slave IC power train is turned on before the master IC and is controlled by the master IC.

If a fault event is detected, then the IC determines which faults events were triggered, such as the power train may be set to enable but it is off due to fault(s), or an external FET is set to enable but the FET is off due to fault(s). The shutdown procedure may include resetting register values and repeating setup steps of enabling the power train, external FET, or other component that is disabled due to a fault. The EXT2 or VIN pins are not configured to detect OVP as it is set as the output in reverse step-up mode. But if EXT2 or VIN pin detects an OVP event, then IC_STATUS1 and IC_STATUS2 would report the fault event.

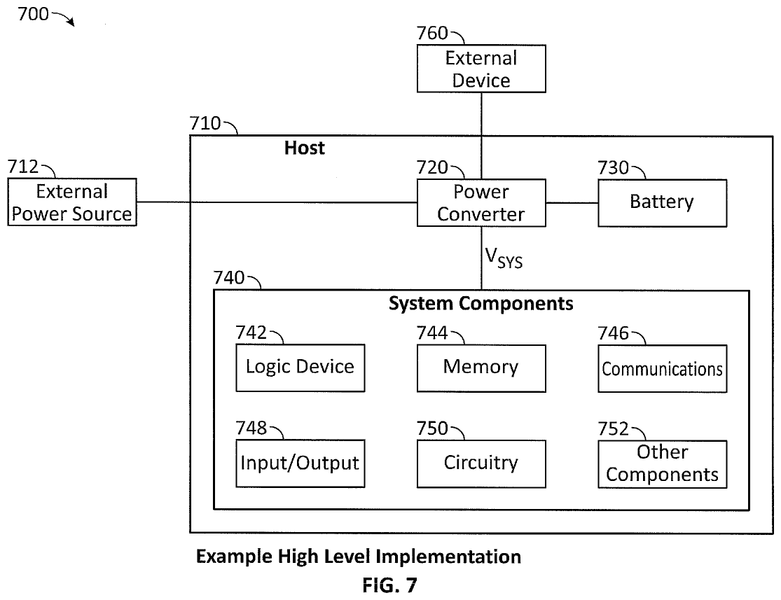

In an example system 700 illustrated in FIG. 7, a power converter 720 is implemented in a host 710 (e.g., a device or system) that includes a battery 730 and various system components 740. The host 710 may be any system or device that implements a power converter as described herein, including but not limited to a smart phone, tablet, portable electronics, a mobile device, low power electronics, and other electronic systems. The battery 730 may include one or more batteries that store electricity for use by the host 710, such as single cell Li-ion and Li-polymer batteries.

The power converter 720 may be configured to convert electricity stored in the battery 730 to a desired system voltage, Vsys, for powering various system components 740, which may include one or more logic devices 742, memories 744, communications components 746, input/output (I/O) components 748, circuitry 750, and other components 752. The power converter 720 may also supply power to one or more external devices 760, such as a component connected to the host 710 through a wired or wireless connection, such as a USB compatible device. The power converter 720 may also be configured to receive power from an external power source 712 and convert the received power to the battery 730 for storage, or to the system components 740 and/or external device 760, as applicable.

In various embodiments, the one or more logic devices 742 and memories 744 may be configured to perform operations of the host 710. A logic device 742 may be implemented as a general-purpose processor, a digital signal processor (DSP), an application-specific integrated circuit (ASIC), a microcontroller, a programmable logic device (PLD), a field-programmable gate array (FPGA), or other programmable logic device(s). The logic device 742 and other components may be configured through hardwiring, software execution, or a combination of both. In various embodiments, the host 710 includes one or more memory devices designed to retain data, such as software instructions for execution by the logic device. The memory may include volatile and non-volatile memories, such as random-access memory (RAM), dynamic RAM (DRAM), static RAM (SRAM), non-volatile random-access memory (NVRAM), read-only memory (ROM), programmable read-only memory (PROM), erasable programmable read-only memory (EPROM), electrically-erasable programmable read-only memory (EEPROM), flash memory, hard disk drives, or other memory types. The logic device may be configured to execute software instructions residing in the memory, thereby accomplishing method steps and operations.

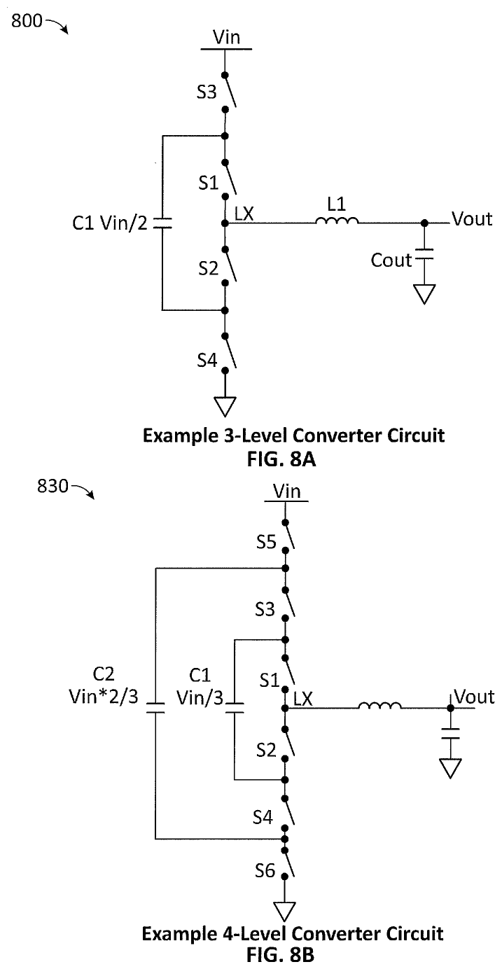

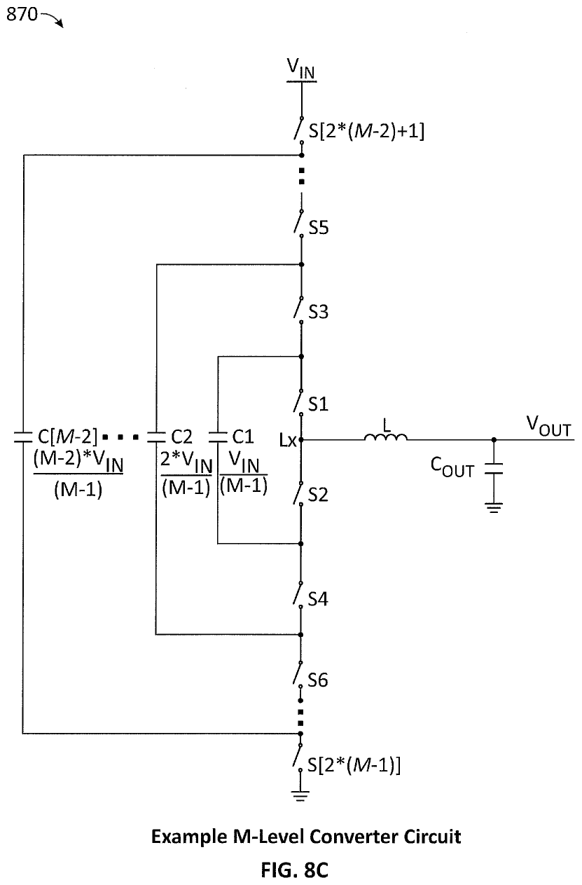

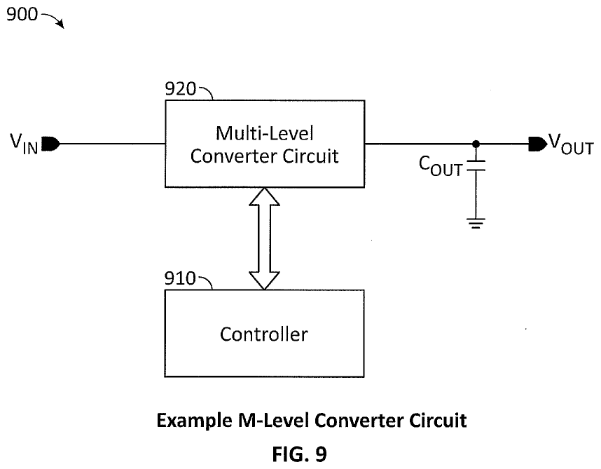

Referring to FIGS. 8A-8C, the converter circuit may be configured to switch between two or more switch states. One or more PWM duty cycle controllers may be provided to set the time in each switch state based on the voltage at VOUT. For example, FIG. 8A is a schematic diagram of a 3-level DC-to-DC buck converter circuit 800 that may be used as the converter circuit 920 of FIG. 9. A set of four switches, S1-S4, is series-coupled between VIN and circuit ground. A fly capacitor C1 is coupled in series with switches S3 and S4, and in parallel with switches S1 and S2. An inductor L1 is coupled to an output capacitor COUT and to a node Lx between switches S1 and S2, and the voltage across the output capacitor COUT is VOUT.

In the illustrated example, the presence of the single fly capacitor C1 in the converter circuit 800 enables four switch states that each generate one of three voltage levels at node Lx. In a first switch state, S2 and S4 are closed and S1 and S3 are open, effectively bypassing C1 and connecting Lx to circuit ground (voltage level at Lx=GND). In a second switch state, S2 and S4 are open and S1 and S3 are closed, effectively bypassing C1 and connecting Lx to VIN (voltage level at Lx=VIN). In a third switch state S1 and S4 are open and S2 and S3 are closed, connecting C1 from VIN to LX, and thus charging C1 with inductor L1 current flowing into a load. The voltage across C1 will be about VIN/2 and the voltage level at Lx will also equal about VIN/2. In a fourth switch state, S1 and S4 are closed and S2 and S3 are open, connecting C1 from Lx to GND and thus discharging C1 with inductor L1 current flowing to a load. The voltage across C1 will be about VIN/2 and the voltage level at Lx will also equal about VIN/2 (e.g., this may assume that C1 was previously charged in state three). Accordingly, the illustrated converter circuit 800 has two switch states that generate a voltage level of VIN/2 at the Lx node.

If the converter circuit 800 is toggled between switch states three and four (avoiding switch state two that bypasses the fly capacitor C1), the inductor L1 sees small jumps in the voltage level at Lx, going from GND to only VIN/2 and back to GND, which results in reduced voltage ripple across the inductor L1 and less filtering to smooth VOUT than a converter circuit with only S1 and S2 switches.

Adding additional series switches Sx and fly capacitors Cx to the 2-level converter circuit 800 increases the number of switch states and resulting voltage levels between VIN and circuit ground that can be applied to the Lx node, thus generating an even smaller voltage ripple across the inductor L. This reduces the filtering requirements to get a smooth output voltage. For example, a 4-level DC-to-DC buck converter circuit (see, e.g., FIG. 8B) includes 6 series-coupled switches S1-S6 and two fly capacitors Cx (X=2). Consequently, a 4-level converter circuit can define 4 voltage levels (VIN, GND, ⅓VIN, and ⅔VIN) at node LX from 8 switch states (3 switch states result in the ⅓VIN level at Lx, and 3 other switch states result in the ⅔ VIN level at Lx). For some applications, VOUT is set low enough that the voltage level at node Lx alternates between GND and the next higher voltage level available. For higher output voltages, the switching pattern may never use GND. For example, in a 4-level converter circuit, an output VOUT set to 0.5*VIN can be achieved by alternating the Lx node between ⅔ VIN and ⅓ V.

A different interpretation of a multi-level converter circuit is that the fly capacitors Cx create a charge-pump for the buck converter circuit. Unlike a standard charge-pump where the output is restricted to one output, a multi-level converter circuit allows the fly capacitors Cx to be coupled to create multiple intermediate voltages. For the 4-level example, the two fly capacitors each act as a ⅓ charge-pump with the additional benefit that any input voltage that is a sum of ⅓ ratios can be created, including VIN and GND.

A multi-level converter circuit couples the fly capacitors Cx in different combinations in order to bring the voltage level at the Lx node down or up. As noted above, when a fly capacitor is used (i.e., not bypassed), the electrical energy flowing through that fly capacitor generally will either charge it or discharge it, which creates a control problem in maintaining an average voltage.

Resolving the charge-balance problem so as to maintain an average voltage across the single capacitor in a 3-level converter circuit will now be described. For example, in a 3-level converter circuit, one way to generate the Level-1 (GND) and Level-3 (VIN) voltage levels at the Lx node is to not use the fly capacitors C1 for these Lx voltage levels. However, for the Level 2 (VIN/2) voltage level at Lx, two separate switch states can be used: one switch state charges the capacitor (S3 and S2 closed, S1 and S4 open) and the other switch state discharges the capacitor (S3 and S2 open, S1 and S4 closed). The control of a 3-level converter circuit may operate such that each time the converter circuit switches states to Level-2, a controller can alternate between charging and discharging the single capacitor to maintain its voltage. A voltage comparator can be used to monitor the capacitor to help decide on a charging state or a discharging state. For instance, if the capacitor voltage is below VIN/2, then a controller would select charge (the third switch state), and if the capacitor voltage is above VIN/2, then the controller would select discharge (the fourth switch state).

Referring to FIGS. 8B, a 4-level converter circuit 830 (X=2) illustrates the charge-balance difficulty when more capacitors are present. A Level-1 voltage level (GND) and a Level-4 voltage level (VIN) at the Lx node are each determined by a single switch state. However, the Level-2 voltage level (⅓ VIN) and Level-3 voltage level (3/3VIN) at Lx each can be achieved by any of three different switch states. At higher orders of a multi-level converter circuit (X>2), more switch states are possible for generating the intermediate levels between VIN and GND. The problem gets more complicated with a 5-level converter circuit (X=3). A Level-1 voltage level (GND) and a Level-5 voltage level (VIN) at the Lx node are each determined by a single switch state. However, the Level-2 voltage level (¼VIN) and Level-4 voltage level (¾ VIN) at Lx each can be achieved by any of four different switch states, the Level-3 voltage level ( 2/4 VIN) at Lx can be achieved by any of six different switch states.

As should be clear from these examples, determining a suitable charge-balance method can become exceedingly difficult as the complexity of a multi-level converter circuit increases. As previously noted, most conventional control methods rely on establishing a sequence of linked state-changes to try to achieve charge balance. Control systems based on long sequences of switch states generally assume that all system variables—such as input voltage and output current—are constant during the sequence. This is unrealistic for a real-world environment, where all system variables tend to be dynamic.

In a 2-Level example, the converter circuit switches between two switch states: S1 closed and S2 open (voltage level at L_{X}=V_{IN}), or S1 open and S2 closed (voltage level at L_{X}=GND). A PWM duty cycle controller sets the time in each switch state based on the voltage at V_{OUT}, which determines the amplitude of the average voltage at L_{X} (noting that, the average L_{X} voltage in theory is equal to the V_{OUT} average voltage, but that, due to parasitics, the L_{X} average voltage is higher and/or lower (for negative currents) than the V_{OUT} average). As can be appreciated, the inductor L sees large jumps in the voltage level at L_{X}, from GND to V_{IN} and back to GND. The resulting voltage ripple across the inductor L necessitates a significant amount of filtering to smooth V_{OUT}.

An alternative way of reducing the voltage ripple across the inductor L is to add more series switches as well as charge transfer capacitors as energy storage elements to transfer charge from V_{IN} to V_{OUT}. As noted above, such charge transfer capacitors are commonly known as “fly capacitors” or “pump capacitors” and may be external components coupled to an integrated circuit embodiment of a converter circuit. The presence of X fly capacitors Cx defines a multi-level capacitive converter circuit capable of generating M=X+2 voltage levels at node Lx from 2^{(X+1)} switch states.

FIG. 8C is schematic diagram of a generalized M-level multi-level converter cell 870 that may be used as the converter circuit 920 of FIG. 9. A set of switches, S1−S[2*(M−1)], is series-coupled between V_{IN} and circuit ground. The set of switches are organized in switch pairs: S1 & S2, S3 & S4, . . . . S[2*(M−2)+1] & S[2*(M−1)]. A set of M−2 fly capacitor Cx is coupled in series with certain respective switches, and in parallel with switches in between those switches. In terms of switch pairs, there are M−1 pairs of switches, or one more than the number of fly capacitors. An optional inductor Lis coupled to an output capacitor C_{OUT} and to a node L_{X} between switches S1 and S2, and again the voltage across the output capacitor C_{OUT} is V_{OUT}. The inductor L doubles as a virtual current source that facilitates movement of charge between the fly capacitors Cx. This creates a very efficient form of charge transfer, but introduces the problem of charge-balancing the fly capacitors Cx.

In various embodiments, each fly capacitor Cx has a first terminal coupled between an outer high-side switch S[2*x+1] and an inner high-side switch S[2*x−1], where “high-side” refers to the V_{IN} side of the converter circuit. Each fly capacitor Cx has a second terminal coupled between an outer low-side switch S[2*x+2] and an inner low-side switch S[2*x], where “low-side” refers to the circuit ground (GND) side of the converter circuit. Thus, for an M=3 multi-level converter cell, a first terminal of the single (X=1) fly capacitor C1 would be coupled between outer high-side switch S3 and inner high-side switch S1, and a second terminal of the capacitor C1 would be coupled between inner low-side switch S2 and outer low-side switch S4. Accordingly, each fly capacitor Cx within the multi-level converter cell 870 has four switches that can affect current flow through that fly capacitor Cx.

In some embodiments, a voltage detector, which may be a simple comparator-type circuit, is provided to sense the voltage across a corresponding fly capacitor Cx with respect to a reference voltage, V_{REF}, which represents a desired target voltage for the fly capacitor Cx. Every fly capacitor Cx may have a target average voltage in order to maintain proper output level. For an M-level converter and capacitor Cx, where x=1, 2, . . . [M−2], its target voltage is:

$$Vtarget [ Cx ] = {V}_{IN} * \frac{x}{M - 1}$$

The voltage detector may be configured to output a HIGH/LOW status signal, C_{Fx_H/L}, indicating with the voltage across the corresponding fly capacitor Cx is greater than V_{REF} or less than V_{REF}. The C_{Fx_H/L} status signal is coupled to control circuitry for the switches associated with the fly capacitor Cx.

The control circuitry for the four switches that can affect current flow through a fly capacitor Cx set states for those switches in part as a function of the voltage across the fly capacitor Cx as measured by the associated voltage detector and conveyed by the C_{Fx_H/L} x status signal. Accordingly, for ease of understanding, it can be said that each fly capacitor Cx “controls” its own pairs of high-side and low-side switches. If it is assumed that current flow in the inductor is charging the output V_{OUT}, there are four possible states that can be defined for the pairs of high-side and low-side switches for each fly capacitor Cx.

In a switch state in which the outer high-side and inner low-side switches associated with fly capacitor Cx are closed and all other associated switches are open, fly capacitor Cx would be in a charging configuration (whether or not charging actually occurs may depend on the switch states for other fly capacitors Cx). In a switch state in which the inner high-side and outer low-side switches associated with fly capacitor Cx are closed and all other associated switches are open, fly capacitor Cx would be in a discharging configuration (whether or not discharging actually occurs may depend on the switch states for other fly capacitors Cx). In a switching state in which the inner low-side and outer low-side switches associated with fly capacitor Cx are closed and all other associated switches are open, fly capacitor Cx would be bypassed. In a switching state in which the outer high-side and inner high-side switches associated with fly capacitor Cx are closed and all other associated switches are open, fly capacitor Cx would again be bypassed.

While each fly capacitor Cx can control both of its own pairs of high-side and low-side switches, in general, methods of control disclosed herein may utilize either the outer switches or the inner switches controllable by each corresponding capacitor. For example, referring to FIG. 8B, in “outer-switch” methods, fly capacitor C1 will control its outer switches S3 and S4, fly capacitor C2 will control its outer switches S5 and S6, etc. Conversely, for example, in “inner-switch” methods, fly capacitor C1 will control its inner switches S1 and S2, fly capacitor C2 will control its inner switches S3 and S4, etc. The switch states of either pair (inner or outer) of switches controlled by a fly capacitor Cx may be complementary—that is, no fly capacitor Cx closes or opens both of its high-side and low-side controlled switches at the same time. If each fly capacitor Cx controls its outer-switches, then no fly capacitor controls the left-over innermost switches S1 and S2. If instead each fly capacitor Cx controls its inner-switches, then no fly capacitor controls the left-over outermost switches S[2*(M−1)] and S[2*(M−2)+1]. Switch states for the left-over switches are also complementary.

FIG. 9 is a high-level block diagram of an example circuit that includes a power converter 900, in accordance with one or more embodiments of the present disclosure. In the illustrated example, the power converter 900 includes a converter circuit 920 and a controller 910. The converter circuit 920 and controller 910 may be configured to implement, for example, any of the multi-level power converter circuits as previously described with reference to FIGS. 1A-8C, and as described further herein. In the illustrated embodiment, the converter circuit 920 is configured to receive an input voltage VIN from a voltage source and transform the input voltage VIN into an output voltage VOUT. In some embodiments of the power converter 900, auxiliary circuitry (not shown), such as a bias voltage generator(s), a clock generator, a voltage control circuit, etc., may also be present and coupled to the converter circuit 920 and the controller 910.

The controller 910 receives a set of input signals and produces a set of output signals. Some of these input signals arrive along a signal path connected to the converter circuit 920. These input signals carry information that is indicative of the operational state of the converter circuit 920. The controller 910 may also receive a clock signal CLK (for synchronous converter circuits 920) and one or more external input/output signals I/O that may be analog, digital (encoded or direct signal lines), or a combination of both. Based upon the received input signals, the controller 910 produces a set of control signals back to the converter circuit 920 that control the internal components of the converter circuit 920 (e.g., internal switches, such as low voltage FETs/MOSFETs) to cause the converter circuit 920 to boost or buck VIN to VOUT. In some embodiments, an auxiliary circuit (not shown) may provide various signals to the controller 910 (and optionally directly to the converter circuit 920), such as the clock signal CLK, the input/output signals I/O, as well as various voltages, such as a general supply voltage VDD and a transistor bias voltage VBIAS.

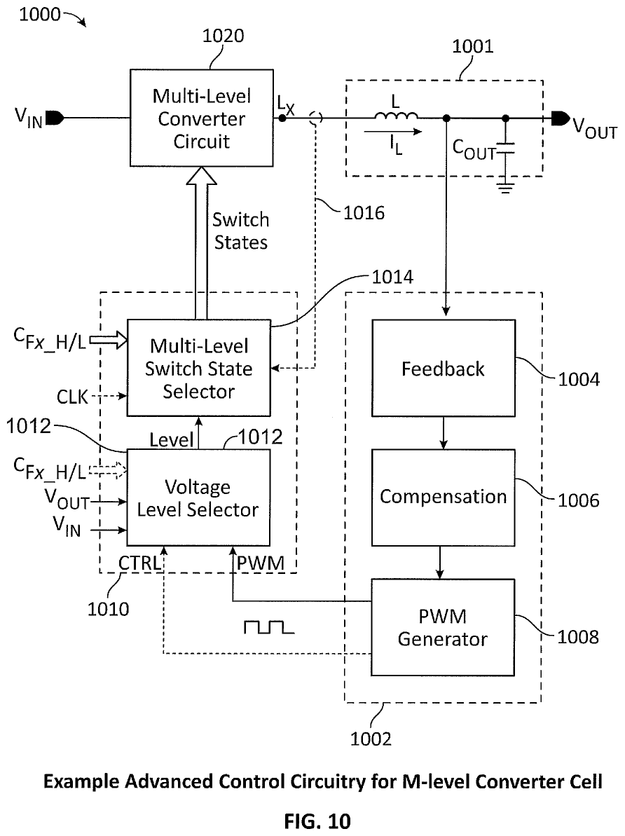

FIG. 10 is a block diagram of one embodiment of advanced control circuitry 1000 for an M-level converter cell 1000 such as the generalized version depicted in FIG. 8B. The M-level converter cell 1020 is shown coupled to an output block 1001 comprising an inductor L and an output capacitor C_{OUT} (conceptually, the inductor L also may be considered as being included within the M-level converter cell 1020). The advanced control circuitry 1000 functions as a control loop coupled to the output of the M-level converter cell 1020 and to switch control inputs of the M-level converter cell 1020. In general, the advanced control circuitry 1000 is configured to monitor the output (e.g., voltage and/or current) of the M-level converter cell 1020 and dynamically generate a set of switch control inputs to the M-level converter cell 1020 that attempt to stabilize the output voltage and/or current at specified values, taking into account variations of V_{IN} and output load. In alternative embodiments, the advanced control circuitry 1000 may be configured to monitor the input of the M-level converter cell 1020 (e.g., voltage and/or current) and/or an internal node of the M-level converter cell 1020 (e.g., the voltage across one or more fly capacitors or the current through one or more power switches). Accordingly, most generally, the advanced control circuitry 1000 may be configured to monitor the voltage and/or current of a node (e.g., input terminal, internal node, or output terminal) of the M-level converter cell 1020. The advanced control circuitry 1000 may be incorporated into, or separate from, the overall controller for a power converter 100 embodying the M-level converter cell 1020.

A first block comprises a feedback controller 1002, which may be a traditional controller such as a fixed frequency voltage mode or current mode controller, a constant-ON-time controller, a hysteretic controller, or any other variant. The feedback controller 1002 is shown as being coupled to V_{OUT} from the M-level converter cell 1020. In alternative embodiments, the feedback controller 1002 may be configured to monitor the input of the M-level converter cell 1020 and/or an internal node of the M-level converter cell 1020. The feedback controller 1002 produces a signal directly or indirectly indicative of the voltage at V_{OUT} that determines in general terms what needs to be done in the multi-level converter cell 1020 to maintain desired values for V_{OUT}: charge, discharge, or tri-state (i.e., open, with no current flow).

In the illustrated example, the feedback controller 1002 includes a feedback circuit 1004, a compensation circuit 1006, and a PWM generator 1008. The feedback circuit 1004 may include, for example, a feedback-loop voltage detector which compares V_{OUT} (or an attenuated version of V_{OUT}) to a reference voltage which represents a desired V_{OUT} target voltage (which may be dynamic) and outputs a control signal to indicate whether V_{OUT} is above or below the target voltage. The feedback-loop voltage detector may be implemented with a comparison device, such as an operational amplifier (op-amp) or transconductance amplifier (gm amplifier).

The compensation circuit 1006 is configured to stabilize the closed-loop response of the feedback controller 1002 by avoiding the unintentional creation of positive feedback, which may cause oscillation, and by controlling overshoot and ringing in the step response of the feedback controller 1002. The compensation circuit 1006 may be implemented in known manner, and may include LC and/or RC circuits.

The PWM generator 1008 generates the actual PWM control signal which ultimately sets the duty cycle of the switches of the multi-level converter cell 1020. In addition, in some embodiments, the PWM generator 1008 may pass on additional optional control signals CTRL indicating, for example, the magnitude of the difference between V_{OUT} and the reference voltage (thus indicating that some levels of the M-level converter cell 1020 should be bypassed to get to higher or lower levels), and the direction of that difference (e.g., whether V_{OUT} is greater than or less than the reference voltage). In other embodiments, the optional control signals CTRL can be derived from the output of the compensation circuit 1006, or from the output of the feedback circuit 1004, or from a separate comparator (not shown) coupled to, for example, V_{OUT}. One purpose of the optional control signals CTRL is for advanced control algorithms, when it may be beneficial to know how far away V_{OUT} is from a target output voltage, thus allowing faster charging of the inductor L if the V_{OUT} is severely under regulated.

A second block comprises a multi-level controller 1010, the primary function of which is to select the switch states that generate a desired V_{OUT} while maintaining a charge-balance state on the fly capacitors within the M-level converter cell 1020 every time an output voltage level is selected, regardless of what switch state or states were used in the past.

The multi-level controller 1010 includes a Voltage Level Selector 1012 which receives the PWM control signal and the additional control signals CTRL if available. In addition, the Voltage Level Selector 1012 may be coupled to V_{OUT} and/or V_{IN}, and, in some embodiments, to the HIGH/LOW status signals, C_{Fx_H/L}, from the voltage detectors coupled to corresponding fly capacitors Cx within the M-level converter cell 1020. A function of the Voltage Level Selector 1012 is to translate the received signals to an output voltage Target Level (e.g., on a cycle-by-cycle basis). The Voltage Level Selector 1012 typically will consider at least V_{OUT} and V_{IN} to determine which Target Level should charge or discharge the output of the M-level converter cell 1020 with a desired rate. For example, in a 6-level converter circuit, the available Target Levels are Level-1 (GND), Level-2 (⅕V_{IN}), Level-3 (⅖V_{IN}), Level-4 (⅗V_{IN}), Level-5 (⅘V_{IN}), and Level-6 (V_{IN}), which may be represented as a count value from 1-6 (or 0-5).

As an example, in a 4-Level converter circuit, if V_{IN}=12V and V_{OUT} nominally should be 3V, then the Voltage Level Selector 1012 may indicate that a Target Level of “2” can be selected, which results in a ⅓V_{IN} voltage level at Lx (i.e., 4V). The PWM control signal sets a duty cycle between that Target Level and another Target Level (e.g., GND) so that the average voltage level at Lx will be about 3V.

In general, for steady-state operations, the Target Level voltage closest to V_{OUT} that either charges or discharges the inductor L may be selected for simplicity of the selection algorithm. In general, for transient response, a Target Level that is higher (for charging) or lower (for discharging) than the closest Target Level may be selected to quickly charge or discharge the inductor L. The Voltage Level Selector 1012 may be implemented, for example, as a look-up table (LUT) or as comparison circuitry and combinatorial logic or more generalized processor circuitry. In some embodiments, the Voltage Level Selector 1012 can implement advanced methods (described below) that try to speed up charging or discharging based on additional factors, such as inductor voltage drop, load transients, the magnitude of output deviations, and/or external input signals from external sources. The output of the Voltage Level Selector 1012 may include duty cycle information (e.g., derived from the input PWM control signal) as well as switch state.

The output of the Voltage Level Selector 1012 is coupled to a Multi-Level Switch State Selector 1014, which generally would be coupled to the status signals, C_{Fx_H/L}, from the voltage detectors for the fly capacitors Cx. Taking into account the Target Level generated by the Voltage Level Selector 1012, the Multi-Level Switch State Selector 1014 determines a pattern of switch states for the desired output level that generally achieves charge-balancing the fly capacitors Cx. The Multi-Level Switch State Selector 1014 may be implemented, for example, as comparison circuitry and combinatorial logic, as a look-up table (LUT), or as more generalized processor circuitry. The output of the Multi-Level Switch State Selector 1014 is coupled to the switches of the multi-level converter cell 1020 (through appropriate level-shifter circuits and drivers circuits, as may be needed for a particular converter cell) and includes a pattern of switch state settings determined by the Multi-Level Switch State Selector 1014. The pattern of switch state settings selects the configuration of the switches within the multi-level converter cell 1020.

In general (but not always), for PWM-based control systems, the Voltage Level Selector 1012 and the M-level Switch State Selector 1014 only change their states when the PWM signal changes. For example, when the PWM signal goes high, the Voltage Level Selector 1012 selects which level results in charging of the inductor L and the M-level Switch State Selector 1014 sets which version to use of that level. Then when the PWM signal goes low, the Voltage Level Selector 1012 selects which level can discharge the inductor L and the M-level Switch State Selector 1014 sets which version of that level to use. Thus, the Voltage Level Selector 1012 and the M-level Switch State Selector 1014 generally only change states when the PWM signal changes (the PWM signal is in effect their clock signal). However, there may be situations or events where it is desirable for the CTRL signal to change the state of the Voltage Level Selector 1012. Further, there may be situations or events where it is desirable for the C_{Fx_H/L} status signal(s) to cause the M-level Switch State Selector 1014 to select a particular configuration of power switch settings, such as when a severe mid-cycle imbalance occurs. In some embodiments, it may be useful to include a timing function that forces the M-level Switch State Selector 1014 to re-evaluate the optimal version of the state periodically, for example, in order to avoid being “stuck” at one level for a very long time, potentially causing charge imbalances.

One notable benefit of the control circuitry shown in FIG. 10 is that it enables generation of voltages in boundary zones between voltage levels, which represent unattainable output voltages for conventional multi-level DC-to-DC converter circuits.

In alternative unregulated charge-pumps embodiments, the feedback controller 1002 and the Voltage Level Selector 1012 may be omitted, and instead a clock signal CLK may be applied to the M-level Switch State Selector 1014. The M-level Switch State Selector 1014 would generate a pattern of switch state settings that periodically charge balances the fly capacitors Cx regardless of what switch state or states were used in the past (as opposed to cycling through a pre-defined sequency of states). This ensures that if V_{IN} changes or anomalous evens occur, the system generally always seeks charge balance for the fly capacitors Cx.

In some embodiments, the M-level Switch State Selector 1014 may take into account the current I_{L} flowing through the inductor L by way of an optional current-measurement input 1016, which may be implemented in conventional fashion.

In an M-level multi-level converter circuit, the configuration of switches that achieves Level-1 (e.g., GND) or Level-M (e.g., V_{IN}) effectively bypasses the fly capacitors Cx. Conversely, for all intermediate voltage levels, at least one fly capacitor Cx is coupled to V_{OUT} and there are always at least two configurations of switches that can achieve any intermediate voltage level. For any particular intermediate voltage level, at least one configuration of switches results in charging the associated fly capacitor and at least one other configuration of switches results in discharging the associated fly capacitor. One aspect of the present disclosure is the realization that any achievable output voltage V_{OUT} requiring intermediate voltage levels can be attained by dynamically selecting patterns of switch configurations—that is, by selecting switch configurations without regard to or memory of the switch configurations of any previous switching cycle—to select appropriate Levels, and doing so in a way that purposefully selects either charging or discharging switch configurations that also balance charge across the fly capacitors Cx.

Embodiments of the disclosure use the following approach for positive inductor L current (charging V_{OUT}):
(1) a fly capacitor Cx that needs charging will be set to close its charging switch (the outer high-side switch in outer-switch control methods, or the inner low-side switch for inner-switch control methods); and
(2) a fly capacitor Cx that needs discharging will be set to close its discharging switch (the outer low-side switch for outer-switch control methods, or the inner high-side switch for inner-switch control methods).

For negative inductor L current (discharging V_{OUT}), the selection of switches inverts. Accordingly:
(1) a fly capacitor Cx that needs charging will be set to close its charging switch (the outer low-side switch in outer-switch control methods, or the inner high-side switch for inner-switch control methods); and
(2) a fly capacitor Cx that needs discharging will be set to close its discharging switch (the outer high-side switch for outer-switch control methods, or the inner low-side switch for inner-switch control methods).

Note again that whether or not charging actually occurs for a particular fly capacitor Cx generally depends on the switch states for all other fly capacitors. For a fly capacitor C(x) to actually charge or discharge, the next inward (if one exists) fly capacitor C(x−1) (for outer-switch control methods) or the previous outward (if one exists) fly capacitor C(x+1) (for inner-switch control methods) must be set to the opposite state (i.e., discharge or charge) so that a bypass situation does not occur.

For any multi-level converter circuit of order M that can create M voltage levels—i.e., Level-1 (e.g., GND) through Level-M (e.g., V_{IN})—then the following switch count rules apply for any Level-m:
(1) M-m low-side switches must be set to be closed (ON);
(2) m-1 high-side switches must be set to be closed (ON); and
(3) switches that are not required to be ON must be set to be OFF (open).

With these switch count rules in mind, the following generalized capacitor control method applies for each state change of the Multi-Level Switch State Selector 1014:
Step 1) Select a fly capacitor that has not previously been selected;
Step 2) If the voltage of the selected fly capacitor is above its Vtarget and there are remaining (i.e., not been set by this method in this cycle) low-side or high-side switches that can be set to be closed to enable a discharge path for the selected fly capacitor, then set those switches that enable a discharge path for the selected fly capacitor to be closed, decrement one or more appropriate counters (e.g., for the number of low-side switches set to be closed and the number of high-side switches set to be closed), and flag the current fly capacitor as “done” (i.e., as having been selected); otherwise (since the voltage of the selected fly capacitor is below its Vtarget) set the switches that enable a charging path for the selected fly capacitor to be closed and flag the current fly capacitor as “done”;
Step 3) Loop to Step 1 until all fly capacitors have been selected;
Step 4) For the remaining pair of left-over switches, set the high-side switch or the low-side switch to be closed based on the switch count rules and the counter values.

With the above generalized capacitor control method, more specific multi-level charge-balancing control methods can be created. Examples can be found, for example, in U.S. Patent Publication No. 20230148059, which is incorporated by reference herein in its entirety.

Many electronic products, particularly mobile computing and/or communication products and components (e.g., cell phones, notebook computers, ultra-book computers, tablet devices, electronic displays) require multiple voltage levels. For example, radio frequency (RF) transmitter power amplifiers may require relatively high voltages (e.g., 12V or more), whereas logic circuitry may require a low voltage level (e.g., 1-2V). Still other circuitry may require an intermediate voltage level (e.g., 5-10V).

Power converters are often used to generate a lower or higher voltage from a common power source, such as a battery, Universal Serial Bus (USB) or USB-C power sources, or a rectified AC power source that is converted to DC. Some power converters, such as multi-level power converters, employ one or more switched capacitor networks. Some multi-level power converters use capacitors as the primary energy storage elements to transfer power from the input to the output of the circuit. A series of switches, such as transistors used as switches, may be used to place a power converter in different states to charge or discharge capacitors as needed. These charge transfer capacitors are commonly known as “fly capacitors” or “pump capacitors” and may be external components coupled to an integrated circuit embodiment of the switches and associated control circuitry.

During operation of multi-level converter circuits, it can be important to carefully maintain the voltage of each fly capacitor within a specified range, such as a fraction of the input voltage. It may be beneficial for the fraction to be maintained, even though the input voltage may “float,” or vary. The states of switches may be changed each clock cycle to maintain an appropriate charge on fly capacitors while at the same time delivering the desired power at the output. For example, a load may be connected and the power converter may deliver power to the load according to the needs of the load, which may vary with time.

Balancing the competing needs of maintaining charge across fly capacitors in multi-level converters while at the same time delivering power to a load according to potentially time-varying needs of the load is challenging. Therefore, there is a need to accurately sense voltage across fly capacitors in a “noisy” environment due to frequent changes of states of switches in multi-level converters to be able to control the level of charge on the capacitors. There is also a need to develop techniques to maintain a desired level of charge on fly capacitors, which are delivering power to a potentially time-varying load, regardless of the power demanded by the load.

### Capacitor Sensing

Exemplary embodiments of capacitor voltage sensing circuits are presented herein. In some embodiments, the sensing circuits sample voltage across a capacitor after a specified delay and compare the sample voltage to a reference target voltage. The reference target voltage a predetermined fraction of an input voltage, or a voltage supplied to an associated power converter, such as a multi-level power converter.

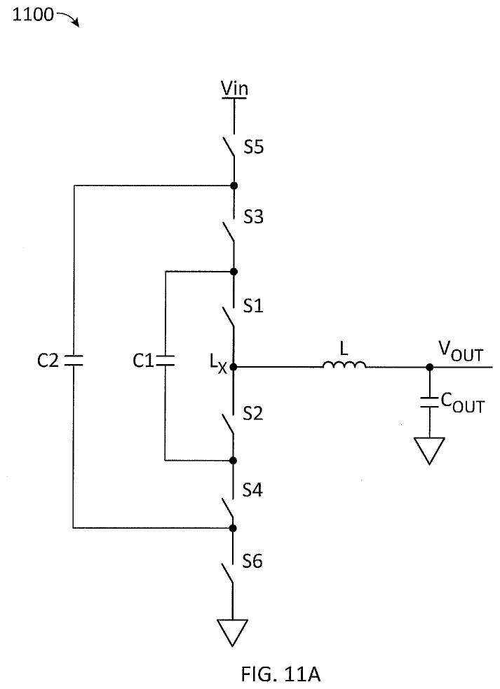

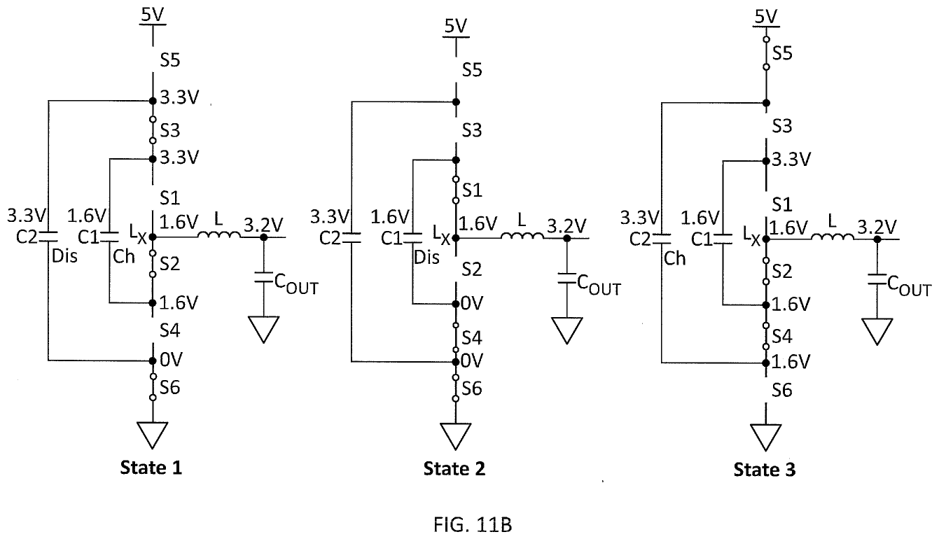

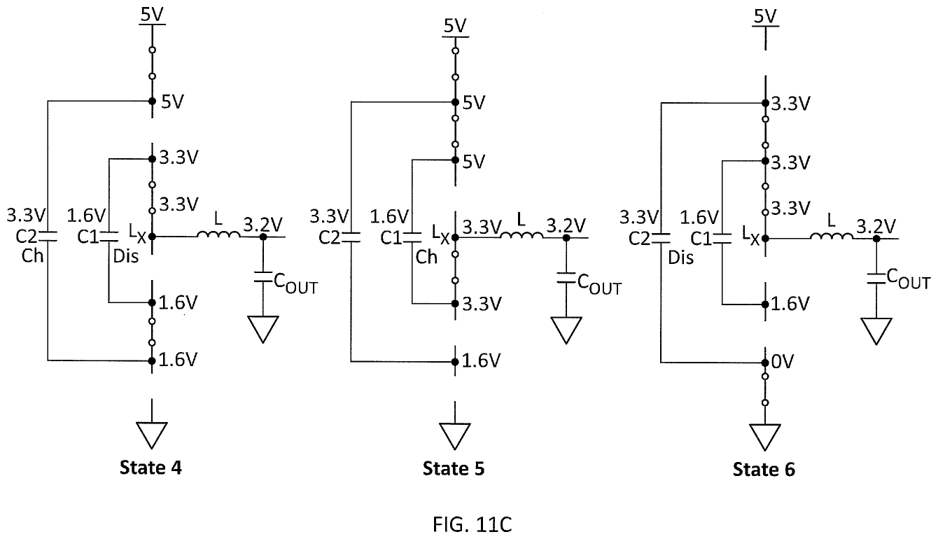

A simplified diagram of an embodiment of a multi-level converter circuit 1100 is illustrated in FIG. 11A, according to some aspects of the disclosure. As shown, the circuit 1100 includes six switches, labeled as S1-S6, connected in series between an input voltage Vin and ground. The circuit 1100 may be referred to as a four-level multi-level converter because the voltage supplied to node Lx can be one of four levels, depending on the states of the switches S1-S6. The switches S1-S6 may be implemented using field-effect transistors (FETs), as understood in the art. For example, the switches S1-S6 may be implemented as FETs, such as FETs Q1-Q6 as shown in FIG. 3, where the on/off (closed/open) state of each FET is controlled by a gate voltage. The circuit 1100 may be coupled to a clock (not shown), and the switches may be controlled such that the state of each switch is set as open or closed and may be changed each clock cycle or some multiple of clock cycles. Each switch S1-S6 may include associated circuitry for controlling the state of the switch. For example, if each switch is implemented using a FET, a level shifter and gate driver may be connected to the gate of the FET to control the on/off state. The level shifter and gate driver may receive an input signal that controls the state of the FET.

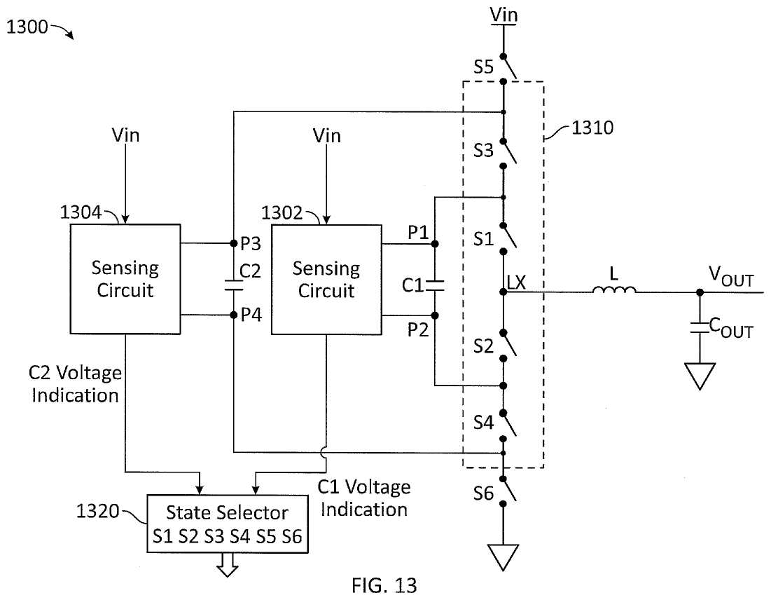

In some embodiments, the series-connected switches S1-S6, along with energy storage elements such as capacitors (e.g., capacitors C1 and C2 in FIG. 13, discussed below), may be referred to as a power converter, and an operating state of the power converter may be referred to as a power state. For example, a power state corresponds to a particular combination of states of switches S1-S6 that may occur during operation of the power converter. The power states may be switched at a specified frequency, such as one megahertz (MHz) or more. The multi-level power converter circuit 1100 includes capacitor C1 and C2 that are charged to a target voltage range during steady-state operation. The voltage across C1 is typically maintained at around Vin/3, and the voltage across C2 is typically maintained at around 2Vin/3.

FIGS. 11B and 11C illustrate multi-level converter circuit 1100 operating in different power states during different regularly occurring time periods, such as during different clock cycles, and for an exemplary input voltage of 5V. In all the power states, the voltage across C2 is maintained at about 2Vin/3, or about 3.3V in this example, and the voltage across C1 is maintained at about Vin/3, or about 1.6V in this example. FIG. 11B illustrates power states labeled as State 1, State 2, and State 3, and all three states yield about the same voltage (of 1.6V) at the node labeled as Lx, where one terminal of the inductor L connects to the series of switches. The state of charging and discharging the capacitors C1 and C2 are also illustrated, using the abbreviations “Dis” for discharge and “Ch” for charge. For example, for the state of the switches shown as State 1, C1 is charging and C2 is discharging (switches S1, S4, and S5 are open and the remaining switches are closed). In State 2, C1 is discharging (Dis); and in State 3, C2 is charging (Ch).

FIG. 11C illustrates power states labeled as State 4, State 5, and State 6, and all three states yield about the same voltage (of 3.3V) at the node labeled as Lx. The charging and discharging states of C1 and C2 are illustrated in FIG. 11C.

During operation of multi-level converter circuits, such as circuit 1100, it can be important to carefully maintain the voltage of each fly capacitor within a specified range. For example, during a normal or steady-state operation of a multi-level power converter circuit, the voltage across C2 is typically maintained within a range around a fraction of Vin, such as 2Vin/3, and the voltage across C1 is typically maintained within a range around a fraction of Vin, such as Vin/3. The voltage fraction may be maintained, even though the input voltage Vin may “float,” or vary. The states of switches S1-S6 may be changed periodically to maintain an appropriate charge on fly capacitors C1 and C2, while at the same time delivering the desired power at the output denoted by Vout in FIG. 11A. For example, a load (not shown) may be connected in parallel with capacitor Cₒᵤₜ, and the circuit 1100 may deliver power to this load according to the needs of the load, which may vary with time.

Balancing the competing needs of maintaining charge across fly capacitors in multi-level converters, such as the circuit 1100, while at the same time delivering power to a load according to potentially time-varying needs of the load is challenging, particularly where the input voltage Vin may also be floating. Therefore, there is a need to accurately sense voltage across fly capacitors in a “noisy” environment due to frequent changes of states of switches in multi-level converters to be able to control the level of charge on the capacitors.

There is also a need to develop techniques to maintain a desired level of charge on fly capacitors, which can be particularly challenging where a time-varying load may enter a “low load” condition, in which output current becomes small or relatively close to zero. For example, in one use case, a multi-level converter may supply power to a processor or other complex integrated circuit as a load, and such a load may enter a dormant or sleep state where little power may be needed.

By carefully switching among States 1-6, target voltages can be maintained across capacitors C1 and C2 while delivering power to a load (not shown) connected in parallel with Cout, according to the needs of the load.

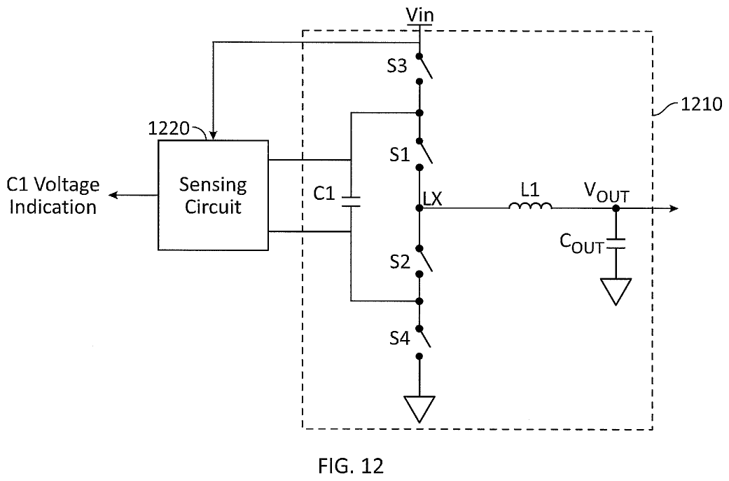

FIG. 12 illustrates an example multi-level power converter circuit 1210 coupled to a sensing circuit 1220, according to some aspects of the disclosure. The multi-level power converter circuit 1210 includes series-connected switches S1-S4 and capacitor C1 as shown. The states of switches S1-S4 may be selected periodically, such as during some multiple of clock cycles. The sensing circuit 1220 provides an indication of voltage across capacitor C1 as compared to a fraction of Vin, which can be used in a control loop to ensure that the voltage across C1 remains in a specified range.

FIG. 13 illustrates another example of a multi-level power converter circuit within a system 1300, according to some aspects of the disclosure. In FIG. 13, the multi-level power converter circuit includes series connected switches S1-S6 and capacitors C1 and C2 connected as shown. The multi-level power converter circuit may also include inductor L and output capacitor Cₒᵤₜ. The system 1300 further includes sensing circuits 1302 and 1304 connected to provide indications of voltages across C1 and C2, respectively. The voltage indications produced by sensing circuits 1302 and 1304 are labeled as “C1 voltage indication” and “C2 voltage indication,” respectively. These voltage indications are provided to a state selector 1320, which may also be referred to as a controller or a state selection circuit. The state selector receives voltage indications as inputs, and selects the states of switches S1-S6 based on voltage indications, as well as potentially other inputs (not shown). The state selector 1320 produces output signals that control the state of each switch S1-S6. For example, there may be one control signal for each of six switches S1-S6, with a control signal being connected to a gate of a switch Sn to control whether the switch is open or closed. As discussed earlier, switches S1-S6 may be implemented using gate-controlled FETs.

Also, as discussed earlier, a given combination of states of switches S1-S6 may be referred to as a power state. The state selector 1320 may be receiving inputs during periodic time periods, such as clock cycles, and selecting the power state for the next time period. In some embodiments, a clock speed may be at least one megahertz (MHz) such that clock cycles and state selections occur at MHz speeds. In some embodiments, all components in system 1300, except for capacitors C1, C2, and Cout and inductor L, are implemented on a single integrated circuit.

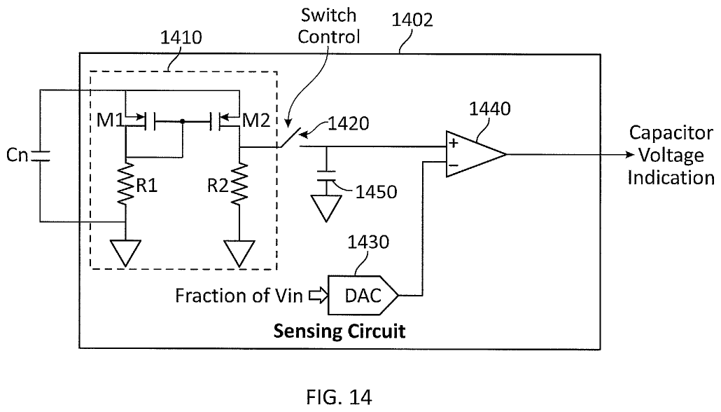

FIG. 14 illustrates an example embodiment of a sensing circuit 1402, according to some aspects of the disclosure. Sensing circuits 1302 and 1304 in FIG. 13 may each be implemented as sensing circuit 1402, for example. The sensing circuit 1402 includes a current mirror 1410. The current mirror 1410 includes MOSFETs M1 and M2 and resistors R1 and R2 connected as shown. The sensing circuit 1402 uses current mirror 1410 to sense the differential voltage across a capacitor Cn, which may be a fly capacitor. The current mirror 1410 includes at least two tunable gain factors. One is gain factor M2/M1 and another is gain factor R2/R1. The factor M2/M1 represents a ratio of a size of M2 divided by a size of M1, and the factor R2/R1 represents a ratio of the resistance of R2 divided by the resistance of R1.

A switch 1420 is connected to an output of the current mirror 1410. To blank transition losses during switching of power states in a multi-level power converter, switch 1420 remains open until the transient noise from a power state transition dies down. A switch control signal is used to open and close switch 1420 as shown, and the switch control signal may delay closing the switch after a power state transition using a delay that is a function of the transition losses of the power converter, such as the power converter in FIG. 13. When switch 1420 is closed the output current charges the holding capacitor 1450 to track the average voltage. A comparator 1440 compares a sample voltage at one input to a voltage reference target to determine if the capacitor Cn is adequately charged. For example, if Cn represents C1 in system 1300, the target voltage may be Vin/3. If Cn represents C2 in system 1300, the target voltage may be 2Vin/3. A digital to analog converter (DAC) 1430 may receive a digitized voltage target, such as Vin/3 or 2Vin/3, and convert the voltage target to analog for use in comparator 1440. Alternatively, the DAC 1430 may employ a variable gain and may scale a digitized value of Vin by an appropriate fraction (e.g., ⅓ or ⅔).

The capacitor voltage indication at the output of comparator 1440 may represent a difference between the capacitor voltage (as represented by the sample voltage) and the target voltage. In one numerical example, the voltage across Cn is 12 V, R1 is 400 kΩ and R2 is 100 kΩ, in which case the voltage measured when switch 1420 is closed is 3V=12*(100/400).

This disclosure recognizes the importance of using a reference target voltage that varies with input voltage (e.g., represented by Vin in FIG. 13). Sensing of voltage of a fly capacitor using a traditional operational transconductance amplifier (OTA) is not suitable in a noisy environment due to the nature of the potentially changing input voltage.

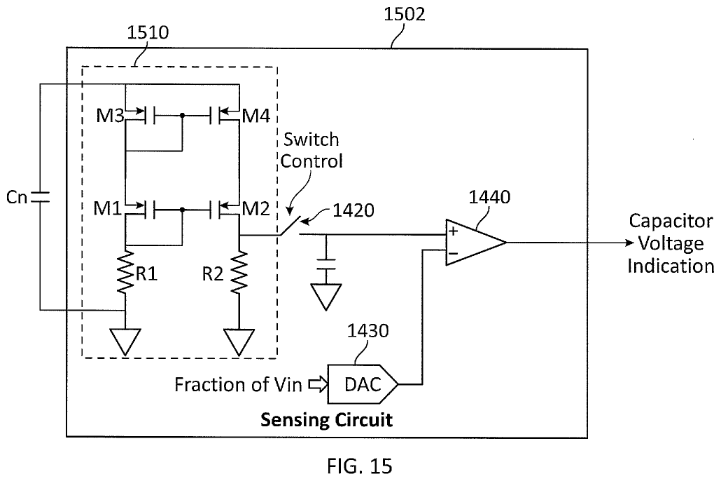

FIG. 15 illustrates another example of a sensing circuit 1502, according to some aspects of the disclosure. The sensing circuit 1502 is essentially the same as the sensing circuit 1402, except for the form of the current mirror 1510. The current mirror 1510 is configured as a cascode current mirror, which has a benefit of making the gain factor M2/M1 more stable. M3 and M4 are MOSFETs.

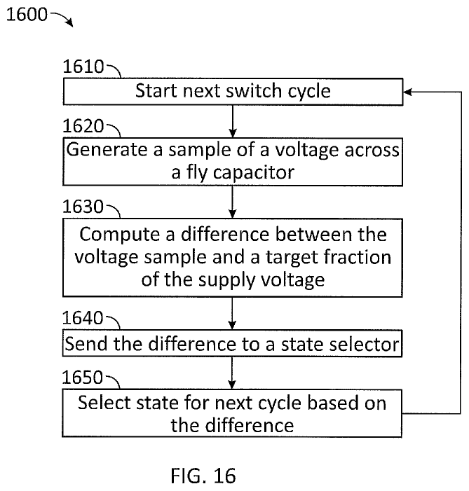

FIG. 16 illustrates an example of a method 1600 of using a multi-state power converter, according to some aspects of the disclosure. The method 1600 may be performed in a multi-state power converter system, such as the system 1300 illustrated in FIG. 13. In step 1610, the next switching cycle is started in which a power state is established for a switchable power converter, such as a multi-level power converter, e.g., as shown in FIG. 13. During this power state, step 1620 is performed in which a sample of voltage across a fly capacitor is generated. FIGS. 14 and 15 illustrate exemplary sensing circuits for providing such a voltage sample. Next, in step 1630, a difference is computed between the voltage sample and a target fraction of the supply voltage. For example, step 1630 may be performed in sensing circuits 1402 or 1502 in FIGS. 14 and 15, respectively. More specifically, the computation of the difference may be performed in a comparator 1440. Next, in step 1640, the difference is transmitted to a state selector that selects the state for the next switching cycle, such as state selector 1320 in FIG. 13. Next, in step 1650, the state is selected based on the difference between the voltage sample and the target fraction of the supply voltage. A state selector 1320 as shown in FIG. 13 may select the state, which specifies the states of switches in a power converter, such as switches S1-S6 in FIG. 13. Thereafter, the method 1600 starts over again. The switching cycle may take place on any periodic time scale, such as a time scale driven by clock cycles. For example, a switch cycle may consist of one or more clock cycles.

### Capacitor Balancing

As explained earlier, there is a need to develop techniques to maintain a desired level of charge on capacitors in a multi-state power converter, in which the capacitors are delivering power to a potentially time-varying load. Systems and methods are disclosed below for maintaining a charge on a capacitor within a target range in a multi-state power converter.

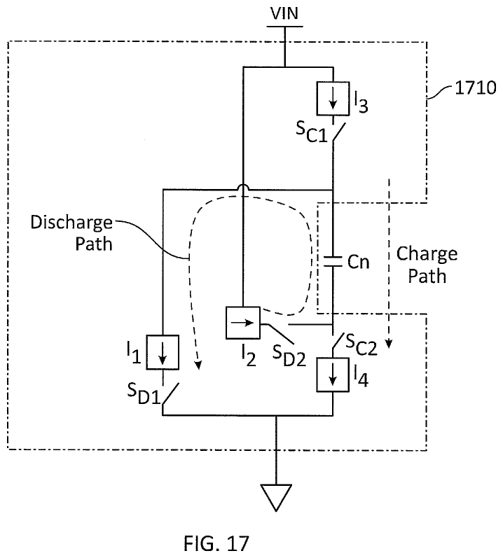

FIG. 17 illustrates a switchable current source network 1710 connected to capacitor Cn, according to some aspects of the disclosure. The switchable current source network 1710 includes current sources I₁-I₄ as well as switches S_{D1}, S_{D2}, S_{C1}, and S_{C2}, and network 1710 is designed to facilitate charging or discharging the capacitor Cn as desired. When current sources I₁ and I₂ are connected to the capacitor Cn by setting discharging switches S_{D1} and S_{D2} in the on state (closed), these current sources form a path for discharging the capacitor Cn. When current sources I₃ and I₄ are connected to the capacitor Cn by setting charging switches S_{C1} and S_{C2} in the on state (closed), these current sources form a path for charging the capacitor Cn. The switchable current source network 1710 may exist in one of three states: (1) switches S_{D1}, S_{D2}, S_{C1}, and S_{C2} are off; (2) switches S_{D1}, S_{D2} are on and S_{C1}, and S_{C2} are off (discharging state); and (3) switches S_{D1}, S_{D2} are off and S_{C1}, and S_{C2} are on (charging state).

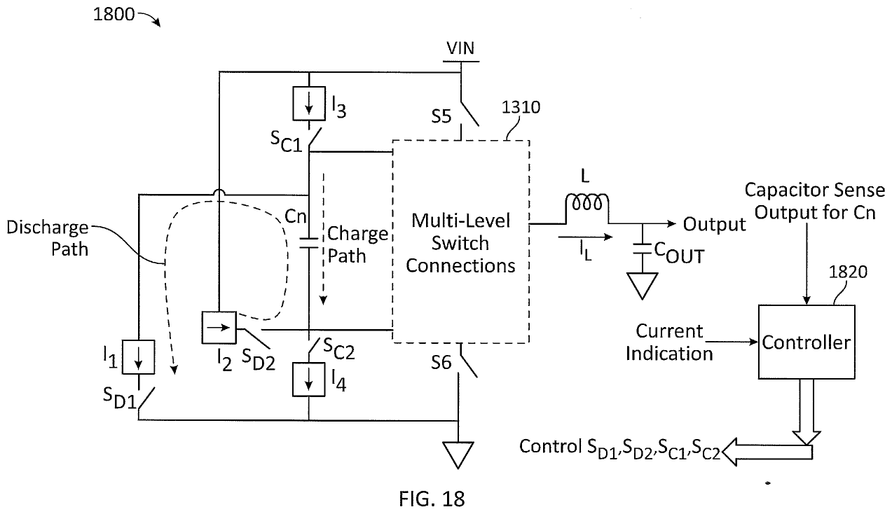

FIG. 18 illustrates an exemplary power converter system 1800, according to some aspects of the disclosure. The power converter system includes series-connected switches S5, S6, and multi-level switch connections 1310. Multi-level switch connections 1310 is a simplified diagram of series-connected switches S1-S4 as shown in FIG. 13.

There is a need to develop techniques to maintain a desired level of charge on fly capacitors, such as capacitor Cn in FIG. 18, in multi-level power converters, which can be particularly challenging where a time-varying load may enter a “low load” condition. In a low-load condition, an output current, such as I_{L} in FIG. 18, becomes small or relatively close to zero. A low-load condition may be a steady-state condition of operation. For convenience, only one capacitor Cn of a power converter system is illustrated in FIG. 18, but there may be other capacitors, such as shown in FIG. 13.

In the power converter system 1800 of FIG. 18, when a measure of output current I_{L} across inductor L indicates that output current I_{L} is low, there remains a need to charge and discharge the capacitors, such as Cn. However, it can be difficult to know which of charging or discharging a capacitor to choose when the output current is low. The controller 1820 in FIG. 18 receives an indication of output current I_{L} as well as an indication of voltage across Cn, e.g., using a capacitor sense circuit as discussed previously. The current I_{L} across inductor L may be measured directly or there may be a proxy for such current measured in the system 1800, such as a measure of current across switch S5 or S6. Any of these measures of current may be referred to as output current.

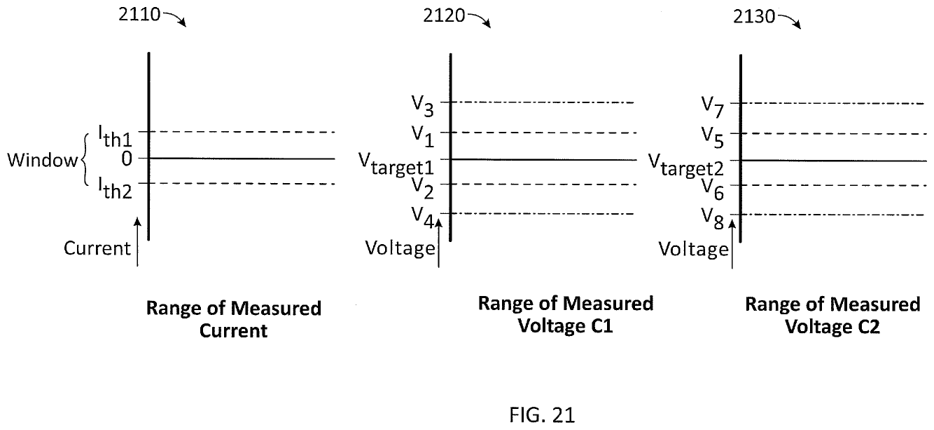

The operation of system 1800 is explained in conjunction with FIG. 21. The range of measured current is represented by graph 2110 in FIG. 21, and measured current will vary with time, so the X-axis may represent time. When measured current falls within the window bounded by thresholds Iₜₕ₁ and Iₜₕ₂, one set of the charging (I₃ and I₄) or discharging (I₁ and I₂) current sources is closed (turned on) via control of charging switches (S_{C1} and S_{C2}) and discharging switches (S_{D1} and S_{D2}). The thresholds Iₜₕ₁ and Iₜₕ₂ may be symmetric about 0, or more generally may be asymmetric. The decision whether to charge or discharge capacitor Cn depends upon the voltage across the capacitor. The controller 1820 receives a current indication and a capacitor sense output (measuring voltage across Cn) and sends control signals to switches S_{C1} and S_{C2} and S_{D1} and S_{D2} based on the current indication and the capacitor sense output For example, if switches S_{C1} and S_{C2} and S_{D1} and S_{D2} are implemented using MOSFETs, the open/closed state of each switch/MOSFET is controlled by the gate voltage of the switch/MOSFET.

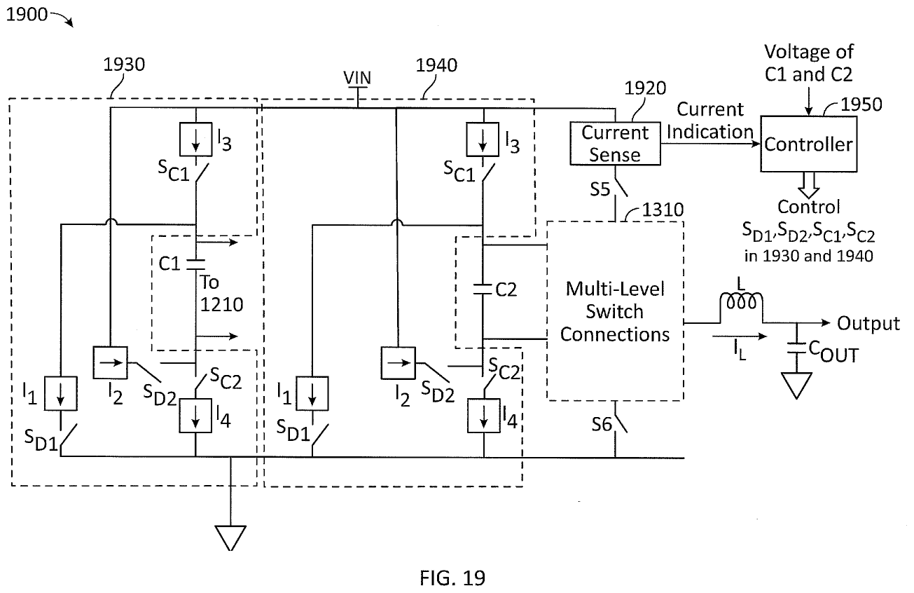

FIG. 19 illustrates another exemplary power converter system 1900, according to some aspects of the disclosure. As shown, the power converter system 1900 includes a first switchable current source network 1930 and a second switchable current source network 1940. The switchable current source networks 1930 and 1940 together form a third switchable current source network. The power converter system 1900 further includes a switchable power conversion network that includes a plurality of series-connected switches S1-S6 (S1-S4 are represented at a high level by 1310) connected between a first voltage terminal or connection Vin and a second voltage terminal or connection, labeled as ground in FIG. 19 but could be implemented using any voltage level. The system 1900 further includes fly capacitors C1 and C2 coupled to the switchable power conversion network, inductor L, and output capacitor Cout. In some embodiments, all components in system 1900, except for capacitors C1, C2, and Cout and inductor L, may be implemented on a single integrated circuit. Each of the switchable current source networks 1930 and 1940 are configurable to charge and discharge capacitors C1 and C2, respectively, as explained previously with respect to FIG. 18.

The system 1900 may further include a current sense device or circuit 1920 for measuring current within the system 1900. The current sense circuit 1920 is shown as connected in series with switch S5 but alternatively may be connected in parallel with S5, depending on the technique used to measure current. The current sense circuit 1920 provides a current indication to a controller 1950. The current indication is a measure of current used to indicate the loading condition at the output of the system 1900. In one embodiment, the current sense circuit 1920 may be implemented as a replica bias circuit, in which a mimic FET is connected in parallel with S5 to have the same voltage as S5, but the mimic FET is smaller than a FET used to implement S5. A circuit could be used to read the voltage across the mimic FET or measure current in the mimic FET to estimate current handled by S5. Alternatively or in addition, a current sense circuit 1920 can be connected to measure current handled by switch S6. If different current sense circuits 1920 are connected to both S5 and S6, an average or some other combination of current measurements from the different current sense circuits can be used as the current indication input to a controller 1950. In operation, a load (not shown) may be connected in parallel with Cₒᵤₜ at the output of the system 1900.

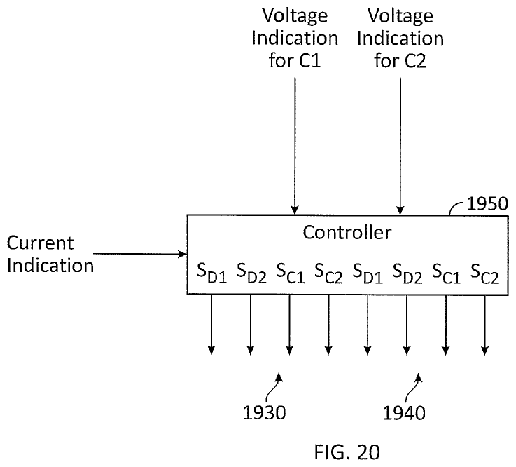

A more detailed illustration of controller 1950 is provided in FIG. 20, according to some aspects of the disclosure. During operation, the controller 1950 receives an indication of current in the system 1900 and a voltage indication for each capacitor C1 and C2. Based on these inputs, the controller 1950 provides control signals for each of switches S_{C1}, S_{C2}, S_{D1}, and S_{D2} in each switchable current source network 1930 and 1940.

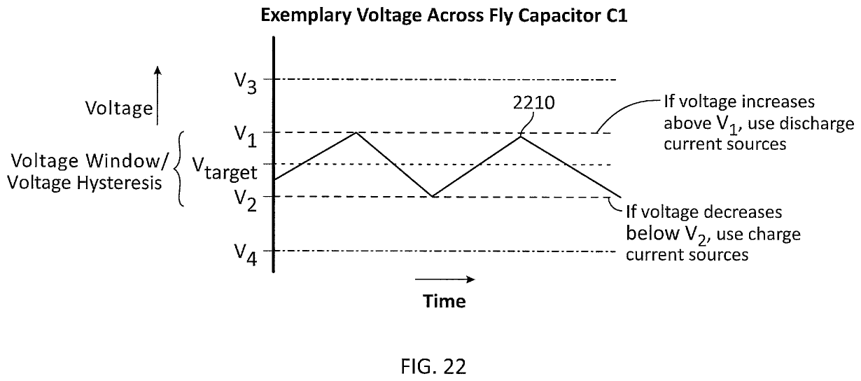

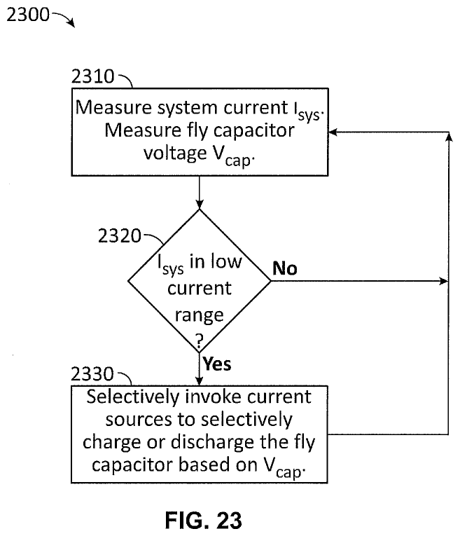

A more detailed description of the operation of controller 1950 is provided in conjunction with FIGS. 21-23. FIG. 22 illustrates an example waveform 2210 representing the voltage across a fly capacitor, such as capacitors C1 or C2. FIG. 23 illustrates an example method 2300, according to some aspects of the disclosure. During a time period, a power state is selected for the switchable power converter network represented by multi-level switch connections 1310 and switches S5 and S6. During this time period, a state of each of the switchable current source networks 1930 and 1940 is also selected. The switches in a switchable current source network 1930 or 1940 may typically exist in one of three states—(1) all switches S_{C1}, S_{C2}, S_{D1}, and S_{D2} are off (or in an open state); (2) charging switches S_{C1} and S_{C2} are turned on (in a closed state) and discharging switches S_{D1} and S_{D2} are turned off, placing the switchable current source network in a charging state to charge the associated capacitor; or (3) charging switches S_{C1} and S_{C2} are turned off and discharging switches S_{D1} and S_{D2} are turned on, placing the switchable current source network in a discharging state to discharge the associated capacitor. The time period may be one of a periodic, repeating set of time periods, such as one or more clock cycles.

During a time period, a current in the system 1900 is measured, according to step 2310 of the method 2300, where the current is represented by I_{sys}. A current may be measured as described previously, such as using current sense circuit 1920 illustrated in FIG. 19 or any other current sense technique known or described herein. Voltages are also measured across each fly capacitor C1 and C2, also according to step 2310. Voltages may be measured, for example, using sensing circuits as illustrated in FIG. 15 or 16. Voltage and current measurements are provided to controller 1950 as shown in FIGS. 19 and 20, and controller 1950 outputs control signals for each of switches in switchable current source networks 1930 and 1940.

Next in step 2320, a determination is made whether I_{sys} is in a low current range, indicating a low load condition. For example, an absolute value of I_{sys} may be compared to a threshold, such as Iₜₕ₁ in FIG. 21, if Iₜₕ₁=−Iₜₕ₂. If I_{sys} is sufficiently small, then the controller 1950 will decide to turn on current sources in the switchable current source networks 1930 and 1940. Whether to charge or discharge capacitors C1 or C2 is determined based on the voltage measured across the capacitors. For example, during steady-state operation, the target voltage for C1 may be Vin/3 and the target voltage for C2 may be 2Vin/3.

If the voltage reading across C1 indicates that the voltage is greater than the target (Vtarget1 in FIG. 21), then the switchable current source network 1930 is placed into a discharge state by controller 1950. If the voltage reading across C1 indicates that the voltage is less than the target (V_{target1} in FIG. 21), then the switchable current source network 1930 is placed into a charge state by controller 1950 (again, by sending signals to close switches S_{C1} and S_{C2} and open switches S_{D1} and S_{D2} in 1930). Charging and discharging C1 may be performed using hysteresis where once a decision is made to charge C1 (or discharge C1), the switchable current source network 1930 is maintained in a charging state (discharging state) until the voltage across C1 is greater than V1 (less than V2), at which point the network 1930 is placed in a discharging state (charging state) until the voltage across C1 is less than V2 (greater than V1), at which point the network 1930 is placed in a charging (discharging) state again. An exemplary waveform representing voltage across C1 is presented as voltage waveform 2210 in FIG. 22. Charging and discharging C1 continues in this manner based on voltage measurements so long as system current measurements (e.g., using current sense circuit 1920) indicate a low-load condition.

In some embodiments, secondary thresholds V3 and V4 are used and secondary current sources (not shown in FIG. 19) are used. If the voltage across C1 exceeds V3, secondary current sources (not shown) for discharging may be additionally switched on to drive down the voltage across C1 faster. Similarly, if voltage across C1 is less than V4, secondary current sources (not shown) for charging may additionally be turned on to drive up the voltage across C1 faster.

Likewise, the controller 1950 controls switchable current source network 1940 for C2 in a similar manner as network 1930 for C1. For example, if the voltage reading across C2 indicates that the voltage is less than the target (V_{target2} in FIG. 21), then the switchable current source network 1940 is placed into a charge state by controller. Charging and discharging C2 may be performed using hysteresis where once the decision is made to charge C2, the switchable current source network 1940 is maintained in a charging state until the voltage across C2 is greater than V5, at which point the network 1940 is placed in a discharging state until the voltage across C1 is less than V6, at which point the network 1940 is placed in a charging state again.

In other embodiments, variable current sources may be used in switchable current source networks 1930 and 1940. The variable current sources may be controlled so that current is increased (linearly or non-linearly) in proportion to deviation of voltage from a target voltage for a given capacitor. As voltage deviation increases, current can be increased proportionally or even in a non-linear manner relative to the voltage increase. Likewise, as voltage deviation decreases, current from current sources can be decreased similarly. For examples, in some embodiments, the current sources I₁-I₄ in each network 1930 and 1940 are variable current sources that increase output current as a load current decreases, and vice versa. Therefore, control of the switchable current source networks may occur via control of current sources instead of, or in addition to, control of switching states.

Further aspects of the present disclosure include the following:
Aspect 1 includes a method comprising: providing a supply voltage to a power converter, wherein the power converter is selectively configurable in one of a plurality of states, and wherein the power converter comprises a fly capacitor; generating a sample of a voltage across the fly capacitor using a sensing circuit to yield a voltage sample, wherein a target voltage across the fly capacitor is a fraction of the supply voltage; computing a difference between the voltage sample and the target voltage; and sending the difference to a state selector configured to select from the plurality of states based on the difference.
Aspect 2 includes the method of aspect 1, further comprising: generating a second sample of a voltage across a second fly capacitor in the power converter using a second sensing circuit to yield a second voltage sample, wherein a second target voltage across the second fly capacitor is a second fraction of the supply voltage; computing a second difference between the second voltage sample and the second target voltage; and sending the second difference to the state selector, wherein the state selector is further configured to select from the plurality of states based on the second difference.
Aspect 3 includes the method of any of aspects 1-2, further comprising: supplying power to a load using the power converter.
Aspect 4 includes the method of any of aspects 1-3, wherein the sensing circuit comprises a switch, wherein the method further comprises: during a first clock cycle: continuing to provide the supply voltage to the power converter; closing the switch after a delay to generate a next sample of the voltage across the fly capacitor, wherein a second target voltage across the fly capacitor is a fraction of the supply voltage during the first clock cycle; computing a second difference between the next sample and the second target voltage; and sending the difference to the state selector for a second clock cycle based on the second difference.
Aspect 5 includes the method of any of aspects 1-4, further comprising: receiving an indication of a selected state from the state selector; and applying the selected state in the power converter, wherein the delay is a function of an amount of time the power converter takes to change states.
Aspect 6 includes a system comprising: a switching circuit connected to a supply voltage terminal, wherein the switching circuit is selectively configurable into a plurality of states, wherein the switching circuit is further configured to connect to a first fly capacitor and a second fly capacitor; a sensing circuit configured to: generate a difference signal representing a difference between a measured voltage across the first fly capacitor and a target fraction of a voltage supplied to the supply voltage terminal; and supply the difference signal to a state selection circuit configured to select from the plurality of states for based on the difference signal.
Aspect 7 includes the system of claim 6, wherein the sensing circuit is further configured to connect to the first fly capacitor, wherein the sensing circuit comprises: a sampling circuit configured to generate the measured voltage as a sample; and a comparator configured to compare the sample with the target fraction to generate the difference signal.
Aspect 8 includes the system of any of aspects 6-7, wherein the sampling circuit comprises: a current mirror configured to connect to the first fly capacitor; a resistor coupled to an output of the current mirror; a capacitor; and a switch connected between the resistor and the capacitor, wherein the sample is generated and provided to the comparator when the switch is in a closed state.
Aspect 9 includes the system of any of aspects 7-8, wherein the sampling circuit comprises: a cascoded current mirror configured to connect to the first fly capacitor; a resistor coupled to an output of the cascoded current mirror; a capacitor; and a switch connected between the resistor and the capacitor, wherein when the sample is generated and provided to the comparator when the switch is in a closed state.
Aspect 10 includes the system of any of aspects 7-9, further comprising: the first fly capacitor and the second fly capacitor connected to the switching circuit; and the state selection circuit, wherein a state selected by the state selection circuit a first state, wherein the state selection circuit is configured to provide switching signals to the switching circuit to configure the switching circuit in the first state.
Aspect 11 includes the system of any of aspects 7-10, wherein the state selection circuit is configured to make a selection from the plurality of states in each of a plurality of consecutive clock cycles, wherein the plurality of consecutive clock cycles is based on a clock running at a speed of at least one megahertz.
Aspect 12 includes the system of any of aspects 7-11, further comprising: a digital to analog converter (DAC), wherein the DAC is configured to receive a measure of the voltage supplied to the supply voltage terminal in digital form and generate the target fraction in analog form for presentation to the comparator.
Aspect 13 includes the system of any of aspects 7-12, wherein the DAC has a programmable gain that converts the measure of the voltage supplied to the supply voltage terminal to the target fraction.
Aspect 14 includes a sensing circuit configured to connect to a first fly capacitor, the sensing circuit comprising: a sampling circuit configured to generate a sample of a measured voltage across the first fly capacitor; and a comparator configured to: receive the sample and a target fraction of a voltage supplied to a power converter; and compare the sample with the target fraction to generate a difference signal that is supplied to a state selection circuit.
Aspect 15 includes the sensing circuit of aspect 14, wherein the sampling circuit comprises: a current mirror configured to connect to the first fly capacitor; a resistor coupled to an output of the current mirror; a capacitor; and a switch connected between the resistor and the capacitor, wherein the sample is generated and provided to the comparator when the switch is in a closed state.
Aspect 16 includes the sensing circuit of any of aspects 14-15, wherein the sampling circuit comprises: a cascoded current mirror configured to connect to the first fly capacitor; a resistor coupled to an output of the cascoded current mirror; a capacitor; and a switch connected between the resistor and the capacitor, wherein the sample is generated and provided to the comparator when the switch is in a closed state.
Aspect 17 includes a system comprising: the sensing circuit any of aspects 14-16; a power converter connected to a supply voltage terminal, wherein the power converter is selectively configurable in one of a plurality of states; the state selection circuit, wherein the state selection circuit is configured to select from the plurality of states based on the difference signal; and the first fly capacitor.
Aspect 18 includes the system of aspect 17, wherein the state selection circuit is configured to make a selection from the plurality of states in each of a plurality of clock cycles, wherein the plurality of clock cycles is based on a clock running at a speed of at least one megahertz.
Aspect 19 includes the system of aspect 17, further comprising: a digital to analog converter (DAC), wherein the DAC is configured to receive a measure of the voltage supplied to the supply voltage terminal in digital form and generate the target fraction in analog form for presentation to the comparator.
Aspect 20 includes the system of any of aspects 17-19, wherein the DAC has a programmable gain that converts the measure of the voltage supplied to the supply voltage terminal to the target fraction.

Further aspects of the present disclosure include the following:
Aspect 1 includes an integrated circuit comprising: a switchable power conversion network configured to connect to a capacitor; a switchable current source network configured to connect to the capacitor, wherein the switchable current source network is switchable among a plurality of states, wherein the plurality of states comprises: a first state in which the switchable current source network is set to apply current to the capacitor in a first direction; a second state in which the switchable current source network is set to apply current to the capacitor in a second direction; and a third state in which the switchable current source network is set in an off state; and wherein a state is selected from among the plurality of states dependent upon a current measurement in the switchable power conversion network.
Aspect 2 includes the integrated circuit of aspect 1, further comprising: a current sense circuit configured to generate the current measurement.
Aspect 3 includes the integrated circuit of any of aspects 1-2, further comprising: a controller configured to: receive the current measurement; select the state; and control the switchable current source network such that the switchable current source network switches to the state.
Aspect 4 includes the integrated circuit of any of aspects 1-3, wherein one of the first state or the second state is selected based on a first condition being satisfied, and wherein the first condition is the current measurement is less than a threshold.
Aspect 5 includes the integrated circuit of any of aspects 1-4, wherein the third state is selected when the current measurement is greater than the threshold.
Aspect 6 includes the integrated circuit of any of aspects 1-5, wherein the state is selected further dependent upon a voltage measurement representative of a voltage across the capacitor.
Aspect 7 includes the integrated circuit of any of aspects 1-6, wherein the first state is selected if the first condition is satisfied and the voltage measurement is greater than a first voltage.
Aspect 8 includes the integrated circuit of any of aspects 1-7, wherein the second state is selected if the first condition is satisfied and the voltage measurement is less than a second voltage, wherein the second voltage is less than the first voltage.
Aspect 9 includes the integrated circuit of any of aspects 1-8, wherein the switchable current source network is connected between a first voltage terminal and a second voltage terminal, wherein the first voltage terminal is configured to be supplied by a first supply voltage, wherein the first direction is toward the first voltage terminal, and wherein the second direction is toward the second voltage terminal.
Aspect 10 includes the integrated circuit of any of aspects 1-8, wherein the first state is maintained while subsequent voltage measurements are greater than the second voltage and subsequent current measurements are less than the threshold.
Aspect 11 includes the integrated circuit of any of aspects 1-10, wherein the second state is maintained while subsequent voltage measurements are less than the first voltage and subsequent current measurements are less than the threshold.
Aspect 12 includes the integrated circuit of any of aspects 1-11, wherein the switchable current source network is further configured to connect to a second capacitor, wherein the switchable power conversion network is switchable among a plurality of power states, wherein each of the plurality of power states represents a different circuit arrangement of the capacitor and the second capacitor, wherein the integrated circuit further comprises: a second switchable current source network configured to connect to the second capacitor, wherein the switchable current source network is switchable among a second plurality of states dependent upon the current measurement and a second voltage measurement representative of a voltage across the second capacitor.
Aspect 13 includes the integrated circuit of any of aspects 1-12, wherein the current measurement is an output current of the switchable power conversion network.
Aspect 14 includes the integrated circuit of any of aspects 1-8, wherein the applied current is proportional to a difference between the voltage measurement and a target voltage.
Aspect 15 includes circuit configured to convert between a first voltage and a second voltage, the circuit comprising: at least one capacitor comprising a capacitor; at least one current source network comprising a current source network, wherein the current source network is switchable among a plurality of states, and wherein the plurality of states comprises a charging state in which a first current charges the capacitor and a discharging state in which a second current discharges the capacitor; a power converter coupled to the at least one capacitor, wherein the power converter is selectively configurable in one of a plurality of power states; and a controller configured to select a state from among the plurality of states based on an operating condition of the power converter and the at least one capacitor.
Aspect 16 includes the circuit of aspect 15, wherein the power converter is configured to connect to a first voltage connection and a second voltage connection, wherein the circuit further comprises: an inductor coupled to the power converter, wherein the first voltage is located at the first voltage connection, and wherein the second voltage is located at a terminal of the inductor; and a current sense circuit connected between the power converter and the first voltage connection or the second voltage connection, wherein the current sense circuit is configured to determine a measurement of a current flowing through the first voltage connection or the second voltage connection as the operating condition.
Aspect 17 includes the circuit of aspects 14-16, wherein the controller is further configured to: receive the measurement; determine the state; and control the at least one current source network such that the current source network switches to the charging state or the discharging state.
Aspect 18 includes the circuit of any of aspects 14-17, wherein the charging state or the discharging state is selected when the measurement is less than a threshold current value.
Aspect 19 includes the circuit of any of aspects 14-18, wherein the plurality of states further comprises an off state, wherein the off state is selected when the measurement is greater than the threshold current value.
Aspect 20 includes the circuit of any of aspects 14-19, wherein the current source network comprises: a first current source for generating the first current; a first pair of switches; a second current source for generating the second current; and a second pair of switches, wherein the first current source, the first pair of switches, and the capacitor are connected in series, wherein the second current source, the second pair of switches, and the capacitor are connected in series, wherein in the charging state, the first pair of switches are in a closed state and the second pair of switches are in an open state, and wherein in the discharging state the first pair of switches are in an open state and the second pair of switches are in a closed state.
Aspect 21 includes method comprising providing an indication that a load connected to a switchable power conversion network is in a low-load operating condition; and selecting between a charge state and a discharge state of a switchable current source network based on the low-load operating condition, wherein the switchable current source network is configurable to charge a capacitor in the charge state and to discharge the capacitor in the discharge state, and wherein the capacitor is configured to supply power to the load.
Aspect 22 includes the method of aspect 21, wherein the selecting is performed to maintain a voltage across the capacitor within a predetermined range.
Aspect 23 includes the method of aspects 21-22, further comprising: providing a measurement of current within the switchable power conversion network, wherein the indication comprises the measurement being less than a threshold.

### General Benefits and Advantages of Multi-Level Power Converters

Embodiments of the current invention improve the power density and/or power efficiency of incorporating circuits and circuit modules or blocks. As a person of ordinary skill in the art should understand, a system architecture is beneficially impacted utilizing embodiments of the current invention in critical ways, including lower power and/or longer battery life. The current invention therefore specifically encompasses system-level embodiments that are creatively enabled by inclusion in a large system design and application.

More particularly, multi-level power converters provide or enable numerous benefits and advantages, including:
adaptability to applications in which input and/or output voltages may have a wide dynamic-range (e.g., varying battery input voltage levels, varying output voltages);
efficiency improvements on the run-time of devices operating on portable electrical energy sources (batteries, generators or fuel cells using liquid or gaseous fuels, solar cells, etc.);
efficiency improvements where efficiency is important for thermal management, particularly to protect other components (e.g., displays, nearby ICs) from excessive heat;
enabling design optimizations for power efficiency, power density, and form-factor of the power converter—for example, smaller-size multi-level power converters may allow placing power converters in close proximity to loads, thus increasing efficiency, and/or to lower an overall bill of materials;
the ability to take advantage of the performance of smaller, low voltage transistors;
adaptability to applications in which power sources can vary widely, such as batteries, other power converters, generators or fuel cells using liquid or gaseous fuels, solar cells, line voltage (AC), and DC voltage sources (e.g., USB, USB-C, power-over Ethernet, etc.);
adaptability to applications in which loads may vary widely, such as ICs in general (including microprocessors and memory ICs), electrical motors and actuators, transducers, sensors, and displays (e.g., LCDs and LEDs of all types);
the ability to be implemented in a number of IC technologies (e.g., MOSFETs, GaN, GaAs, and bulk silicon) and packaging technologies (e.g., flip chips, ball-grid arrays, wafer level scale chip packages, wide-fan out packaging, and embedded packaging).

The advantages and benefits of multi-level power converters enable usage in a wide array of applications. For example, applications of multi-level power converters include portable and mobile computing and/or communication products and components (e.g., notebook computers, ultra-book computers, tablet devices, and cell phones), displays (e.g., LCDs, LEDs), radio-based devices and systems (e.g., cellular systems, WiFi, Bluetooth, Zigbee, Z-Wave, and GPS-based devices), wired network devices and systems, data centers (e.g., for battery-backup systems and/or power conversion for processing systems and/or electronic/optical networking systems), internet-of-things (IOT) devices (e.g., smart switches and lights, safety sensors, and security cameras), household appliances and electronics (e.g., set-top boxes, battery-operated vacuum cleaners, appliances with built-in radio transceivers such as washers, dryers, and refrigerators), AC/DC power converters, electric vehicles of all types (e.g., for drive trains, control systems, and/or infotainment systems), and other devices and systems that utilize portable electricity generating sources and/or require power conversion.

Radio system usage includes wireless RF systems (including base stations, relay stations, and hand-held transceivers) that use various technologies and protocols, including various types of orthogonal frequency-division multiplexing (“OFDM”), quadrature amplitude modulation (“QAM”), Code-Division Multiple Access (“CDMA”), Time-Division Multiple Access (“TDMA”), Wide Band Code Division Multiple Access (“W-CDMA”), Global System for Mobile Communications (“GSM”), Long Term Evolution (“LTE”), 5G, and WiFi (e.g., 802.11a, b, g, ac, ax), as well as other radio communication standards and protocols.

### Programmable Embodiments

Some or all aspects of the invention, particularly the Multi-Level Switch State Selector 1014 of FIG. 10, may be implemented in hardware or software, or a combination of both (e.g., programmable logic arrays). Unless otherwise specified, the algorithms included as part of the invention are not inherently related to any particular computer or other apparatus. In particular, various general purpose computing machines may be used with programs written in accordance with the teachings herein, or it may be more convenient to use a special purpose computer or special-purpose hardware (such as integrated circuits) to perform particular functions. Thus, embodiments of the invention may be implemented in one or more computer programs (i.e., a set of instructions or codes) executing on one or more programmed or programmable computer systems (which may be of various architectures, such as distributed, client/server, or grid) each comprising at least one processor, at least one data storage system (which may include volatile and non-volatile memory and/or storage elements), at least one input device or port, and at least one output device or port. Program instructions or code may be applied to input data to perform the functions described in this disclosure and generate output information. The output information may be applied to one or more output devices in known fashion.

Each such computer program may be implemented in any desired computer language (including machine, assembly, or high-level procedural, logical, or object-oriented programming languages) to communicate with a computer system, and may be implemented in a distributed manner in which different parts of the computation specified by the software are performed by different computers or processors. In any case, the computer language may be a compiled or interpreted language. Computer programs implementing some or all of the invention may form one or more modules of a larger program or system of programs. Some or all of the elements of the computer program can be implemented as data structures stored in a computer readable medium or other organized data conforming to a data model stored in a data repository.

Each such computer program may be stored on or downloaded to (for example, by being encoded in a propagated signal and delivered over a communication medium such as a network) a tangible, non-transitory storage media or device (e.g., solid state memory media or devices, or magnetic or optical media) for a period of time (e.g., the time between refresh periods of a dynamic memory device, such as a dynamic RAM, or semi-permanently or permanently), the storage media or device being readable by a general or special purpose programmable computer or processor for configuring and operating the computer or processor when the storage media or device is read by the computer or processor to perform the procedures described above. The inventive system may also be considered to be implemented as a non-transitory computer-readable storage medium, configured with a computer program, where the storage medium so configured causes a computer or processor to operate in a specific or predefined manner to perform the functions described in this disclosure.

### Fabrication Technologies & Options

In various embodiments of multi-level power converters, it may be beneficial to use specific types of capacitors, particularly for the fly capacitors. For example, it is generally useful for such capacitors to have low equivalent series resistance (ESR), low DC bias degradation, high capacitance, and small volume. Low ESR is especially important for multi-level power converters that incorporate additional switches and fly capacitors to increase the number of voltage levels. Selection of a particular capacitor should be made after consideration of specifications for power level, efficiency, size, etc. Various types of capacitor technologies may be used, including ceramic (including multi-layer ceramic capacitors), electrolytic capacitors, film capacitors (including power film capacitors), and IC-based capacitors. Capacitor dielectrics may vary as needed for particular applications, and may include dielectrics that are paraelectric, such as silicon dioxide (SiO₂), hafnium dioxide (HFO₂), or aluminum oxide Al₂O₃. In addition, multi-level power converter designs may beneficially utilize intrinsic parasitic capacitances (e.g., intrinsic to the power FETs) in conjunction with or in lieu of designed capacitors to reduce circuit size and/or increase circuit performance. Selection of capacitors for multi-level power converters may also take into account such factors as capacitor component variations, reduced effective capacitance with DC bias, and ceramic capacitor temperature coefficients (minimum and maximum temperature operating limits, and capacitance variation with temperature).

Similarly, in various embodiments of multi-level power converters, it may be beneficial to use specific types of inductors. For example, it is generally useful for the inductors to have low DC equivalent resistance, high inductance, and small volume.

The controller(s) used to control startup and operation of a multi-level power converter may be implemented as a microprocessor, a microcontroller, a digital signal processor (DSP), register-transfer level (RTL) circuitry, and/or combinatorial logic.

The term “MOSFET”, as used in this disclosure, includes any field effect transistor (FET) having an insulated gate whose voltage determines the conductivity of the transistor, and encompasses insulated gates having a metal or metal-like, insulator, and/or semiconductor structure. The terms “metal” or “metal-like” include at least one electrically conductive material (such as aluminum, copper, or other metal, or highly doped polysilicon, graphene, or other electrical conductor), “insulator” includes at least one insulating material (such as silicon oxide or other dielectric material), and “semiconductor” includes at least one semiconductor material.

As used in this disclosure, the term “radio frequency” (RF) refers to a rate of oscillation in the range of about 3 kHz to about 300 GHz. This term also includes the frequencies used in wireless communication systems. An RF frequency may be the frequency of an electromagnetic wave or of an alternating voltage or current in a circuit.

With respect to the figures referenced in this disclosure, the dimensions for the various elements are not to scale; some dimensions have been greatly exaggerated vertically and/or horizontally for clarity or emphasis. In addition, references to orientations and directions (e.g., “top”, “bottom”, “above”, “below”, “lateral”, “vertical”, “horizontal”, etc.) are relative to the example drawings, and not necessarily absolute orientations or directions.

Various embodiments of the invention can be implemented to meet a wide variety of specifications. Unless otherwise noted above, selection of suitable component values is a matter of design choice. Various embodiments of the invention may be implemented in any suitable integrated circuit (IC) technology (including but not limited to MOSFET structures), or in hybrid or discrete circuit forms. Integrated circuit embodiments may be fabricated using any suitable substrates and processes, including but not limited to standard bulk silicon, high-resistivity bulk CMOS, silicon-on-insulator (SOI), and silicon-on-sapphire (SOS). Unless otherwise noted above, embodiments of the invention may be implemented in other transistor technologies such as bipolar, BiCMOS, LDMOS, BCD, GaAs HBT, GaN HEMT, GaAs pHEMT, and MESFET technologies. However, embodiments of the invention are particularly useful when fabricated using an SOI or SOS based process, or when fabricated with processes having similar characteristics. Fabrication in CMOS using SOI or SOS processes enables circuits with low power consumption, the ability to withstand high power signals during operation due to FET stacking, good linearity, and high frequency operation (i.e., radio frequencies up to and exceeding 300 GHz). Monolithic IC implementation is particularly useful since parasitic capacitances generally can be kept low (or at a minimum, kept uniform across all units, permitting them to be compensated) by careful design.

Voltage levels may be adjusted, and/or voltage and/or logic signal polarities reversed, depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functionality without significantly altering the functionality of the disclosed circuits.

Circuits and devices in accordance with the present invention may be used alone or in combination with other components, circuits, and devices. Embodiments of the present invention may be fabricated as integrated circuits (ICs), which may be encased in IC packages and/or in modules for ease of handling, manufacture, and/or improved performance. In particular, IC embodiments of this invention are often used in modules in which one or more of such ICs are combined with other circuit blocks (e.g., filters, amplifiers, passive components, and possibly additional ICs) into one package. The ICs and/or modules are then typically combined with other components, often on a printed circuit board, to form part of an end product such as a cellular telephone, laptop computer, or electronic tablet, or to form a higher-level module which may be used in a wide variety of products, such as vehicles, test equipment, medical devices, etc. Through various configurations of modules and assemblies, such ICs typically enable a mode of communication, often wireless communication.

A number of embodiments of the disclosure have been described. It is to be understood that various modifications may be made without departing from the spirit and scope of the disclosure. For example, some of the steps described above may be order independent, and thus can be performed in an order different from that described. Further, some of the steps described above may be optional. Various activities described with respect to the methods identified above can be executed in repetitive, serial, and/or parallel fashion.

It is to be understood that the foregoing description is intended to illustrate and not to limit the scope of the disclosure, which is defined by the scope of the following claims, and that other embodiments are within the scope of the claims. In particular, the scope of the disclosure includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

What is claimed is:

1. A method comprising:
providing a supply voltage to a power converter, wherein t3 he power converter is selectively configurable in one of a plurality of states, and wherein the power converter comprises a fly capacitor;
generating a sample of a voltage across the fly capacitor using a sensing circuit to yield a voltage sample, wherein a target voltage across the fly capacitor is a fraction of the supply voltage;
computing a difference between the voltage sample and the target voltage; and
sending the difference to a state selector configured to select from the plurality of states based on the difference.

2. The method of claim 1, further comprising:
generating a second sample of a voltage across a second fly capacitor in the power converter using a second sensing circuit to yield a second voltage sample, wherein a second target voltage across the second fly capacitor is a second fraction of the supply voltage;
computing a second difference between the second voltage sample and the second target voltage; and
sending the second difference to the state selector, wherein the state selector is further configured to select from the plurality of states based on the second difference.

3. The method of claim 1, further comprising:
supplying power to a load using the power converter.

4. The method of claim 1, wherein the sensing circuit comprises a switch, wherein the method further comprises:
during a first clock cycle:
continuing to provide the supply voltage to the power converter;
closing the switch after a delay to generate a next sample of the voltage across the fly capacitor, wherein a second target voltage across the fly capacitor is a fraction of the supply voltage during the first clock cycle;
computing a second difference between the next sample and the second target voltage; and
sending the difference to the state selector for a second clock cycle based on the second difference.

5. The method of claim 4, further comprising:
receiving an indication of a selected state from the state selector; and
applying the selected state in the power converter,
wherein the delay is a function of an amount of time the power converter takes to change states.

6. A system comprising:
a switching circuit connected to a supply voltage terminal, wherein the switching circuit is selectively configurable into a plurality of states, wherein the switching circuit is further configured to connect to a first fly capacitor and a second fly capacitor;
a sensing circuit configured to:
generate a difference signal representing a difference between a measured voltage across the first fly capacitor and a target fraction of a voltage supplied to the supply voltage terminal; and
supply the difference signal to a state selection circuit configured to select from the plurality of states for based on the difference signal.

7. The system of claim 6, wherein the sensing circuit is further configured to connect to the first fly capacitor, wherein the sensing circuit comprises:
a sampling circuit configured to generate the measured voltage as a sample; and
a comparator configured to compare the sample with the target fraction to generate the difference signal.

8. The system of claim 7, wherein the sampling circuit comprises:
a current mirror configured to connect to the first fly capacitor;
a resistor coupled to an output of the current mirror;
a capacitor; and
a switch connected between the resistor and the capacitor, wherein the sample is generated and provided to the comparator when the switch is in a closed state.

9. The system of claim 7, wherein the sampling circuit comprises:
a cascoded current mirror configured to connect to the first fly capacitor;
a resistor coupled to an output of the cascoded current mirror;
a capacitor; and
a switch connected between the resistor and the capacitor, wherein when the sample is generated and provided to the comparator when the switch is in a closed state.

10. The system of claim 7, further comprising:
the first fly capacitor and the second fly capacitor connected to the switching circuit; and
the state selection circuit, wherein a state selected by the state selection circuit a first state, wherein the state selection circuit is configured to provide switching signals to the switching circuit to configure the switching circuit in the first state.

11. The system of claim 7, wherein the state selection circuit is configured to make a selection from the plurality of states in each of a plurality of consecutive clock cycles, wherein the plurality of consecutive clock cycles is based on a clock running at a speed of at least one megahertz.

12. The system of claim 7, further comprising:
a digital to analog converter (DAC), wherein the DAC is configured to receive a measure of the voltage supplied to the supply voltage terminal in digital form and generate the target fraction in analog form for presentation to the comparator.

13. The system of claim 12, wherein the DAC has a programmable gain that converts the measure of the voltage supplied to the supply voltage terminal to the target fraction.

14. A sensing circuit configured to connect to a first fly capacitor, the sensing circuit comprising:
a sampling circuit configured to generate a sample of a measured voltage across the first fly capacitor; and
a comparator configured to:
receive the sample and a target fraction of a voltage supplied to a power converter; and
compare the sample with the target fraction to generate a difference signal that is supplied to a state selection circuit.

15. The sensing circuit of claim 14, wherein the sampling circuit comprises:
a current mirror configured to connect to the first fly capacitor;
a resistor coupled to an output of the current mirror;
a capacitor; and
a switch connected between the resistor and the capacitor, wherein the sample is generated and provided to the comparator when the switch is in a closed state.

16. The sensing circuit of claim 14, wherein the sampling circuit comprises:
a cascoded current mirror configured to connect to the first fly capacitor;
a resistor coupled to an output of the cascoded current mirror;
a capacitor; and
a switch connected between the resistor and the capacitor, wherein the sample is generated and provided to the comparator when the switch is in a closed state.

17. A system comprising:
the sensing circuit of claim 16;
a power converter connected to a supply voltage terminal, wherein the power converter is selectively configurable in one of a plurality of states;
the state selection circuit, wherein the state selection circuit is configured to select from the plurality of states based on the difference signal; and
the first fly capacitor.

18. The system of claim 17, wherein the state selection circuit is configured to make a selection from the plurality of states in each of a plurality of clock cycles, wherein the plurality of clock cycles is based on a clock running at a speed of at least one megahertz.

19. The system of claim 17, further comprising:
a digital to analog converter (DAC), wherein the DAC is configured to receive a measure of the voltage supplied to the supply voltage terminal in digital form and generate the target fraction in analog form for presentation to the comparator.

20. The system of claim 19, wherein the DAC has a programmable gain that converts the measure of the voltage supplied to the supply voltage terminal to the target fraction.
